(19) United States
(12) Patent Application Publication
(10) Pub. No.: US 2025/0065297 A1
(43) Pub. Date: Feb. 27, 2025

(54) METHODS FOR SELF-SEEDED HYDROTHERMAL GROWTH OF MFI ZEOLITE NANOSHEETS AND NANOSHEET ASSEMBLIES AND FOR TILING NANOSHEET ZEOLITE PLATES ON POLYMER SUPPORTS

(71) Applicant: University Of Cincinnati, Cincinnati, OH (US)

(72) Inventors: Junhang Dong, Cincinnati, OH (US); Zishu Cao, Whitehouse, TX (US); Landysh Iskhakova, Mason, OH (US)

(21) Appl. No.: 18/727,023

(22) PCT Filed: Jan. 9, 2023
(86) PCT No.: PCT/US2023/010426

§ 371 Date: Jul. 5, 2024

Related U.S. Application Data
(60) Provisional application No. 63/297,442, filed on Jan. 7, 2022.
(60) Provisional application No. 63/427,428, filed on Nov. 22, 2022.

(51) Int. Cl. B01J 20/10; B01J 20/28; B01J 20/30; B01J 20/32; C30B 7/14; C30B 29/34; C30B 29/66; H01M 8/1086; H01M 8/18

(52) U.S. Cl. CPC B01J 20/103; B01J 20/28016; B01J 20/28026; B01J 20/3021; B01J 20/3057; B01J 20/3071; B01J 20/3085; B01J 20/3208; B01J 20/3225; B01J 20/3238; C30B 7/14; C30B 29/34; C30B 29/66; H01M 8/1086; H01M 8/109; H01M 8/188

(57) ABSTRACT

The present invention relates to methods for synthesizing MFI zeolite nanosheet (ZN) assemblies and open-pore ZN plates and for tiling ZN plates on polymer supports. Methods for producing ZN assemblies and ZN plates may reduce or eliminate the need to synthesize nanoparticle (NP) seed-evolved single-crystal zeolite nanosheets (ZNs) as an intermediate product. Methods for tiling ZN plates on polymer supports may produce ZN plate-tiled (ZNPT) membranes with reduced permeation through intercrystalline spaces.

### CROSS-REFERENCE TO RELATED APPLICATIONS

This application claims the benefit of the filing date of U.S. Provisional Application No. 63/297,442, filed on Jan. 7, 2022, and U.S. Provisional Application No. 63/427,428, filed on Nov. 22, 2022, the disclosures of which are incorporated herein by reference in their entireties.

### STATEMENT REGARDING FEDERALLY FUNDED RESEARCH DEVELOPMENT

This invention was made with government support under DE-SC0020011 awarded by the U.S. Department of Energy, and CBET-1935205 awarded by the National Science Foundation. The government has certain rights in the invention.

### FIELD OF THE INVENTION

The present invention relates to methods of generating zeolites and methods of tiling zeolite nanosheet plates on polymer supports.

### BACKGROUND OF THE INVENTION

This section is intended to introduce the reader to various aspects of art that may be related to various aspects of the present invention, which are described and/or claimed below. This discussion is believed to be helpful in providing the reader with background information to facilitate a better understanding of various aspects of the present invention. Accordingly, it should be understood that these statements are to be read in this light, and not as admissions of prior art.

Zeolites are crystalline aluminosilicates containing ordered pores of molecular dimensions well-suited for molecular catalysis and separations in petrochemical, biochemical reactions, energy production processes. Zeolites with small and medium pore openings, such as the zeolite A (LTA) and MFI types, can achieve perfect selectivity to water and proton permeation over hydrated metal ions by molecule and ion sieving effects. Thus, zeolite membranes can be useful to high-efficiency proton-conduction in electrolyte solutions and desalination of concentrated brines for which traditional polymer membranes are inefficient. The MFI-type zeolites are particularly desirable for such applications because their pore openings (approximately 0.56 nm) are close to the maximum width (approximately 0.60 nm) allowing total rejection of metal ions and hence can achieve low resistances to water and proton (mainly H₃O⁺) transport with high selectivity. The porous structure of zeolites makes them highly effective for catalysis due, at least in part, to the proportionally higher number of active sites for catalytic reactions arising from increased surface area.

In recent years, there have been successful syntheses of two-dimensional (2D) zeolite nanosheets (ZNs) with thicknesses of one or two unit-cells. These 2D ZNs maximize the accessibility of active surface sites and micropores for adsorbing molecules and catalyzing reactions. Meanwhile, the ultrathin ZNs minimize the diffusion length that overcomes molecular transport limitations in catalysis and separation processes. The 2D ZNs and their hierarchical assemblies thus offer significantly enhanced performances in heterogeneous catalysis and molecular separations. The 2D ZNs with large lateral-to-thickness aspect ratios can also laminate ultrathin membranes of desired orientations to reduce the transmembrane diffusion resistance and nonselective intercrystalline entrances leading to simultaneous improvements in permeability and selectivity.

Despite the tremendous potentials demonstrated on small-sized samples, the development of practical ZN adsorbents, catalysts, and membranes has been hampered by the lack of methods for efficient synthesis of redispersible activated ZNs with well-preserved micropore accessibility and surface properties. In the literature, medium pore size MWW and MFI type ZNs with thickness of one- or two-unit cells were obtained by exfoliation from layered zeolite precursors (LZPs) synthesized using diquaternary or triquaternary ammonium structure directing agents (SDAs). The exfoliated single crystalline ZNs are typically 100-400 nm in lateral lengths. These small-size ZNs tend to aggregate and deform, which can cause difficulties in reassembling useful macrostructures. For example, aggregation of ZNs often results in non-selective or less selective structures which allows for increased permeation through intercrystalline spaces rather than through the zeolite pores, thereby reducing the efficacy of the ZN membranes in separation applications. Recently, a nanoparticle-seeded secondary growth method was developed to directly produce isolated single crystalline MFI ZNs using diquaternary bis-1,5(tripropyl ammonium) pentamethylene diiodide (dC5) as the SDA. However, the as-synthesized ZN crystal contains an isotropic core grown from the spherical seed, which must be eliminated by tedious processes to achieve flat ZNs. Methods for obtaining flat ZNs by LZP exfoliation and seeded secondary growth methods are both prohibitively complex with extremely low yields. The difficult redispersion of activated ZNs also limits the fabrication of ZN-laminated membranes on economical polymer substrates. Therefore, a need still exists for an efficient method to synthesize ZN assemblies and for an efficient method to prepare highly dispersed open-pore ZN materials for tiling a polymer substrate with ZN plates to form molecular and ion separation membranes.

Accordingly, there is a need for a method for producing zeolite nanosheet assemblies that does not require removing the seed core to form a flat zeolite nanosheet. Additionally, there is a need for a method of producing zeolite nanosheet plates with large areas for use in application such as zeolite nanosheet plate-tiled polymer membranes.

### SUMMARY OF THE INVENTION

Certain exemplary aspects of the invention are set forth below. It should be understood that these aspects are presented merely to provide the reader with a brief summary of certain forms the invention might take and that these aspects are not intended to limit the scope of the invention. Indeed, the invention may encompass a variety of aspects that may not be explicitly set forth below.

One aspect of the invention is directed to a method for synthesizing flower-like zeolite nanosheet (ZN) assemblies from pure-silica MFI (silicalite) ZN flake seeds, the method including (a) obtaining ZN flake seeds; and (b) growing single-crystal nanosheets from the ZN flake seeds to form ZN assemblies in a synthesis solution comprising a source of silica and a structure directing agent (SDA).

In one embodiment of the invention, the synthesis solution of step (b) comprises diquaternary bis-1,5(tripropyl ammonium) pentamethylene diiodide (dC5) as an SDA.

In one embodiment of the invention, the synthesis solution of step (b) comprises tetraethyl orthosilicalite (TEOS) as a source of silica. In a further embodiment, the synthesis solution of step (b) further comprises diquaternary bis-1,5(tripropyl ammonium) pentamethylene diiodide (dC5) as an SDA. In a yet further embodiment, the synthesis solution of step (b) further comprises a base.

In one embodiment of the invention, obtaining the ZN flake seeds in step (a) is preceded by producing the ZN flake seeds, wherein producing the ZN flake seeds includes (i) generating silicalite nanoparticles (NPs) in a silicalite synthesis solution comprising a source of silica and a structure directing agent (SDA) to produce NP seeds; (ii) growing single crystalline silicalite ZNs from the NP seeds using a ZN precursor solution comprising an SDA to produce seed-evolved ZNs; (iii) cleaning the seed-evolved ZNs; and (iv) fracturing the cleaned seed-evolved ZNs to produce ZN flake seeds.

In one such embodiment, the source of silica in the silicalite synthesis solution includes tetraethyl orthosilicate (TEOS).

In one such embodiment, the SDA of the silicalite nanoparticle seed synthesis solution comprises tetrapropyl ammonium hydroxide (TPAOH).

In one such embodiment of the invention, the SDA of the ZN precursor solution comprises diquaternary bis-1,5(tripropyl ammonium) pentamethylene diiodide (dC5).

In one such embodiment of the invention, the ZN precursor solution further comprises a source of silica. In a further embodiment thereof, the source of silica of the ZN precursor solution comprises tetraethyl orthosilicalite (TEOS).

In one such embodiment of the invention, the ZN precursor solution is hydrolyzed prior to step (ii).

In one such embodiment of the invention, cleaning the seed-evolved ZNs comprises subjecting the seed-evolved ZNs to at least one base treatment step.

In one such embodiment of the invention, cleaning the seed-evolved ZNs comprises subjecting the seed-evolved ZNs to at least one base-chloride treatment step.

In one such embodiment of the invention, fracturing the seed-evolved ZNs comprises ball milling. In a further embodiment, fracturing the seed-evolved ZNs comprises sonicated ball milling in water.

In one such embodiment of the invention, the synthesis solution of step (b) comprises diquaternary bis-1,5(tripropyl ammonium) pentamethylene diiodide (dC5) as an SDA.

In another embodiment where obtaining the ZN flake seeds in step (a) is preceded by producing the ZN flake seeds, wherein producing the ZN flake seeds comprises: (i) obtaining a ZN assembly; (ii) cleaning the ZN assembly; and (iii) fracturing the ZN assembly to produce ZN flake seeds.

In one such embodiment of the invention, obtaining a ZN assembly comprises obtaining a ZN assembly produced according to step (b)

In one such embodiment of the invention, cleaning the ZN assembly comprises subjecting the ZN assembly to at least one base treatment step.

In one such embodiment of the invention, cleaning the ZN assembly comprises subjecting the ZN assembly to at least one base-chloride treatment step.

In one such embodiment of the invention, wherein fracturing the ZN assembly comprises ball milling. In a further embodiment, fracturing the ZN assembly comprises sonicated ball milling in water

In one embodiment of the invention, growing single crystal nanosheets comprises growing multilayered ZN plates. In a further embodiment, the multilayered ZN plates comprise greater than or equal to 2 single-crystal ZN layers and less than or equal to 20 single crystal ZN layers.

Another aspect of the invention is directed to a method for producing a polymer support zeolite nanosheet plate-tiled (ZNPT) membrane comprising: (a) obtaining ZN plates; (b) dispersing the ZN plates in a polymer tiling solution comprising a solvent, an amount of dissolved polymer binders, and a binder solvent to form a ZN plate dispersion; (c) tiling the ZN plate dispersion onto a polymer substrate to form a ZN plate layer; (d) drying the ZN plate layer on the polymer substrate after step (c); and (e) curing the ZN plate layer coated on the polymer substrate after step (d) to form a polymer-support ZNPT membrane.

In one embodiment of the invention, step (a) for obtaining ZN plates is preceded by producing the ZN plates, wherein producing the ZN plates comprises: (i) obtaining a ZN assembly; (ii) cleaning the ZN assembly; and (iii) fracturing the ZN assembly in a liquid solvent to produce ZN plates. In one embodiment of the invention, the method further includes step (iv) for activating the ZN assembly prior to fracturing the ZN assembly. In one such embodiment, activating the ZN assembly comprises calcination in air at a temperature greater than or equal to 400° C.

In one such embodiment of the invention, obtaining a ZN assembly comprises synthesizing a ZN assembly according to the aspect of the invention detailed above.

In one such embodiment of the invention, cleaning the ZN assembly comprises subjecting the ZN assembly to at least one base treatment step.

In one such embodiment of the invention, cleaning the ZN assembly comprises subjecting the ZN assembly to at least one base-chloride treatment step.

In one such embodiment of the invention, fracturing the ZN assembly comprises ball milling. In a further embodiment of the invention, fracturing the ZN assembly comprises sonicated ball milling in an organic solvent. In a yet further embodiment of the invention, the organic solvent comprises ethanol.

In one embodiment of the invention, the amount of dissolved polymer binders of step (b) comprises polyvinylidene fluoride (PVDF).

In one embodiment of the invention, the solvent of step (b) comprises ethanol.

In one embodiment of the invention, the binder solvent of step (b) comprises dimethyl sulfoxide (DMSO). In a further embodiment, the solvent of step (b) comprises ethanol. In a yet further embodiment, the weight ratio of ethanol to DMSO is 2:1.

In one embodiment of the invention, the ZN plates comprise greater than or equal to 0.01 wt. % by weight of the polymer tiling solution of step (b).

In one embodiment of the invention, step (c) comprises: (i) placing the polymer substrate between the ZN plate dispersion and a downstream compartment; and (ii) applying a pressure driving force to the ZN plate dispersion to tile the ZN plates onto the polymer substrate using filtration coating. In one such embodiment, applying a pressure driving force comprises applying a downstream vacuum. In one such embodiment, applying a pressure driving force comprises applying an upper stream pressurization.

In one embodiment of the invention, step (d) comprises subjecting the ZN plate layer on the polymer substrate to a temperature greater than or equal to 80° C. for a period of time greater than or equal to 3 hours. In a further embodiment, step (d) further includes pulling a vacuum at a pressure less than or equal to 1.5 kPa during step (d).

In one embodiment of the invention, step (e) comprises subjecting the ZN plate layer on the polymer substrate to a temperature greater than or equal to 120° C. for a period of time greater than or equal to 3 hours. In a further embodiment, step (e) further includes pulling a vacuum at a pressure less than or equal to 24 kPa during step (e).

### BRIEF DESCRIPTION OF THE DRAWINGS

The accompanying drawings, which are incorporated in and constitute a part of this specification, illustrate embodiments of the invention and, together with the general description of the invention given above, and the detailed description given below, serve to explain the principles of the invention. Similar reference numerals are used to indicate similar features throughout the various figures of the drawings.

FIG. 1 is a series of microscopic images showing the process of ZN flake seed growth into flower-like ZN-assembly: (A) scanning electron microscopy (SEM) image of a typical ZN fragment seed; (B) and (C) are SEM and transmission electron microscopy (TEM) images of a typical rhombus sheet obtained in 0.5-day reaction; (D) TEM image of a rhombus sheet obtained by 1-day reaction; (E) TEM image of an extensively cleaned ZN from 1-day reaction; (F) high resolution (HR) TEM image of a local spot in the sample of (E); (G) and (H) are SEM images of typical crystals after growing for 2 and 3 days, respectively.

FIG. 2 is a series of images showing the first-generation flower-like ZN assemblies: (A) seeds of ball-milled single crystalline ZNs prepared by reference method Jeon et al, Ultra-selective high-flux membranes from directly synthesized zeolite nanosheets, Nature. 543 (2017) 690; (B) a ZN assembly of rose-like architecture, (C) ZN assemblies of spiral leaf structure, and (D) unfractionated flat ZN plates disintegrated from the ZN flowers.

FIG. 3 is a series of images showing single-step growth of ZN assemblies by self-seeding with ground ZN plates: (A) schematic showing the self-seeded cyclic reproduction of ZN flowers; (B) small fragment seeds from the 1st generation flowers; (C) the 2nd generation ZN flower; (D) small fragment seeds from second-generation flowers, and (E) the 3rd generation ZN flowers.

FIG. 4 is a series of images showing the microstructure of ZN plates forming the flower-like assemblies: (A) TEM image and electron diffraction (ED) pattern of a multilayered plate edge; (B) TEM images and ED pattern of an exfoliated single-crystal sheet; (C) XRD spectra of the ZN flowers and a layer of flat ZN plates; (D) AFM height survey over the areas of multilayered ZN plates (insert: side-view SEM of a layer with multiple ZN plates); (E) AFM height survey over the area of a single crystal ZN sheet; and (F) and (G) are height-profiles of the multilayered ZN plates and the single crystal sheet along lines in (D) and (E), respectively.

FIG. 5 is a series of images showing (A) SEM picture of flower-like ZN assemblies after thermal activation and adsorption tests (insert TEM image showing flower-structure integrity); (B) SEM picture of conventional silicalite crystals; (C) N₂ adsorption-desorption curves for the ZN flowers before and after activation; (D) pore size distributions of the ZN flowers before and after activation; (E) dynamic adsorption curves for p-xylene, o-xylene, and equimolar p-xylene/o-xylene mixture vapors on the ZN assemblies and conventional silicalite crystals at 300 K and p/pₒ approximately 0.05; (F) schematic showing accessibility of zeolitic pores to p-xylene and o-xylene molecules in conventional crystals; (G) schematic showing accessibility of intra- and intercrystalline micropore system to p-xylene and o-xylene molecules in the multilayered ZN plates; (H) topological structure of the 3D channel system in MFI zeolite crystals.

FIG. 6A is a schematic showing the step-by-step procedure for preparation of the first-generation ZN seed using the direct synthesis method.

FIG. 6B is a series of SEM and TEM images showing the zeolite crystal structure at different stages of the silicalite nanoparticle (NP) seeded secondary growth process. The ZN fragments used as the seeds were separated from the center cores of the rhombus shaped ZN-crystals via sonicated ball-milling and centrifugal segregation processes, i.e., step 7 in (a). The flat ZN flakes obtained by step (7) in (a) were further ground into smaller pieces by high-energy ball-milling. The SEM images in (b) present the typical crystal morphology at different stages of ZN growth from the initial NP seed. The ZN growth mechanism of a-c faced flat ZN encircling the NP seed was consistent with the observations made by Jeon et al, Ultra-selective high-flux membranes from directly synthesized zeolite nanosheets, Nature. 543 (2017) 690-694.

FIG. 7 is a series of images showing AFM height survey for the rhombus ZNs produced by dC5-directed secondary growth of ZN seeds after 12-h reaction: (A) area profile; (B) line-scan profiles; (C) TEM image of early-stage rhombus sheet; (D) TEM images and electron diffraction patterns showing crystalline area and amorphous nanoparticles attached to the sheet in (C). The AFM results show the epitaxially grown ZN area had a uniform thickness of 4 nm and a ZN seed-evolved 10-20-nm tall plateau formed in the center.

FIG. 8 is a series of images showing A typical rhombus sheet grown from the ZN seeds after 1-day reaction (same as shown in FIG. 1D): (A) TEM image; (B) TEM image showing a-c faced new ZNs rising vertically from the rhombus base ZN grown from the seed; (C) SEM of ZN-seed surface with orthogonal growth of ZN plates; and (D) a local area of sample in FIG. 1E showing defects in a-c face that may develop into the 1-2 nm intra and inter-sheet micropores.

FIG. 9 is a schematic depicting the nucleation and crystal evolution during the ZN self-seeded growth of flower-like ZN assemblies (TEM image in lower right corner showing the large ZN petals grown from the small ZN seed base).

FIG. 10 is a pair of graphs showing N₂ adsorption-desorption results of the thermally activated conventional silicalite crystals: (a) N₂ adsorption-desorption isotherms for conventional silicalite crystals at 77 K; and (B) pore size distribution of the conventional silicalite crystals in comparison with the flower-like ZN assemblies.

FIG. 11 is a series of images showing the silicalite nanoparticle (NP) seeds and single layer ZNs generated by secondary growth: (a) SEM image of the seeds (diameters approximately 30 nm), (b) SEM picture of the as-synthesized rhombus crystals, (c) AFM height survey of the single crystalline flat ZNs (insert: SEM of ZNs after treatment in the KOH solution), and (d) height profiles of ZNs along lines indicated in (c).

FIG. 12 is a series of images showing characterizations of ZN assemblies and dissociated ZN plates: (a) SEM image of the single crystalline ZN seeds, (b) SEM image of ZN assemblies, (c) SEM image of flat ZN plates disintegrated from the ZN assemblies, (d) SEM image of small ZN plate debris revealing multilayered structure, (e) AFM height survey of a ZN plate, (f) AFM height survey of a single crystalline ZN exfoliated from the ZN plates, (g) TEM image and electron diffraction patterns at multilayered layered (upper) and single-layered (lower) locations in ZN plates, (f) XRD patterns of the ZN assemblies and ZN plates film tiled on glass.

FIG. 13 is a series of images showing microscopic characterizations of the ZNPT-PVDF membrane: (a) cross-section of the porous PVDF substrate, (b) surface of the substrate, (c) cross-section of the ZNPT-PVDF membrane, (d) surface of the ZNPT membrane layer, (e) EDS line scanning along the ZNPT-PVDF thickness, and (f) DES elemental imaging survey for Si and F distributions over the ZNPT-PVDF cross-section.

FIG. 14 is a series of images showing schematics showing ion transport pathways in the ZNPT-PVDF membrane: (a) bimodal pore system including zeolitic channels only accessible to proton and water and the inter-ZN plate spaces allowing both proton and metal ion diffusion, (b) surface tiled by large and uniform ZN plates, and (c) surface tiled by nonuniform ZN plates (from residual after separating large ZN plates).

FIG. 15 is a series of graphs showing measurements of ion diffusion through membranes: (a) C_{p,i} vs. t for bare PVDF and the NA-ZNPT-PVDF, (b) C_{p,i} vs. t for ZNPT-PVDF, (c) C_{p,i} vs. t for Nafion117®, and (d) Jᵢ and α_{H/V} for different membrane layers.

FIG. 16 is a series of images showing results of EIS tests for membranes in 2M H₂SO₄: (a) EIS spectra and (b) overall ASR of multilayered membranes, and ASRₘ and σₘ of the individual membrane layers.

FIG. 17 is a series of images showing performances of ZNPT-PVDF and Nafion117 membranes as ion separators for Vanadium RFB: (a) charge-discharge curves at current densities of 30 and 90 mA/cm², respectively, (b) CE, VE, and EE from charge-discharge data in (a), (c) polarization curves and corresponding power density (Pe) dependencies on current density, (d) EIS spectra of the RFB in charged electrolyte solutions.

FIG. 18 is a series of images showing porous PVDF film stability in the highly oxidizing and acidic solution of 2M (VO₂)₂SO₄ (^{V5+})+2M H₂SO₄ (i.e., high concentration catholyte of vanadium RFB): (a) fresh sample, (b) sample after 6-month treatment in the solution, and (c) sample weight as a function of time in solution.

FIG. 19 is a series of images showing (a) a photograph of the vacuum-assisted filtration coating apparatus and (b) a schematic showing the self-repairing mechanism of the filtration coating process.

FIG. 20 is an image showing the RFB single cell used for measurements of EIS, RFB charge-discharge, and RFB polarization curves.

FIG. 21 is a series of images showing zeolite samples and pore size distributions: (a) SEM image of the flower-like ZN assemblies after SDA removal by calcination in air at 550° C. for 6 hours, (b) regular brick-shaped silicalite crystals, and (c) pore size distributions of the activated ZN assemblies and regular crystals.

FIG. 22 is a series of images showing ZNPT-PVDF membranes from suspensions with ZN plate contents that were too low or too high to avoid defect formation: (a) and (b) SEM picture of the ZNPT membrane from suspension containing 0.01 wt. % ZN plates and results of its ion diffusion test, respectively; and (c) and (d) SEM picture of the membrane from suspension with 0.06 wt. % ZN plates and results of its ion diffusion test, respectively. The same amounts of suspension (3.5 mL) were used for total filtration membrane coating and thus the thickness was expected to be approximately 250 nm for the former and approximately 1.5 μm for the latter. The J_{H+}, Jᵥ₄₊, and α_{H/V} estimated from mixture permeation data in (b) and (d) are summarized and compared with the ZNPT-PVDF membrane from suspension containing 0.02 wt. % ZN plates in Table 2.

FIG. 23 is a series of SEM images of the NZ-ZNPT-PVDF synthesized under same conditions as used for ZNPT-PVDF membrane preparation: (a) cross-section and (b) surface.

FIG. 24 is a graph showing use of polarization curves for RFB and IEM property analyses: the linear sections of the polarization curves for estimating the ASR for the ZNPT-PVDF and Nafion117 membrane under RFB operation conditions.

FIGS. 25A and 25B are flow or process diagrams for methods of synthesizing ZN assemblies from ZN flake seeds in accordance with the present invention.

FIGS. 26A and 26B are flow or process diagrams for a method of tiling a polymer substrate with ZN plates in accordance with the present invention.

### DETAILED DESCRIPTION OF EMBODIMENTS OF THE INVENTION

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

In one embodiment, the present invention is a self-seeded single-step synthesis method for efficient reproduction of flower-like ZN-assemblies comprising very large single-crystal nanosheets of about two unit-cells in thickness. Another embodiment of the invention is a method for forming ZN plates from a flower-like ZN assemblies. Yet another embodiment of the invention is a method for forming ZN plates from single crystal ZN seeds. Microscopic investigations were carried out to understand the ZN-seeded crystal growth mechanisms and unveil the microstructure and pore system of the ZN plates and ZN assemblies. The ZN materials were demonstrated with markedly enhanced molecular adsorption and transport properties using xylenes as probing molecules. Another embodiment of the invention is directed to a method for using ZNs and/or ZN plates to tile a polymer substrate.

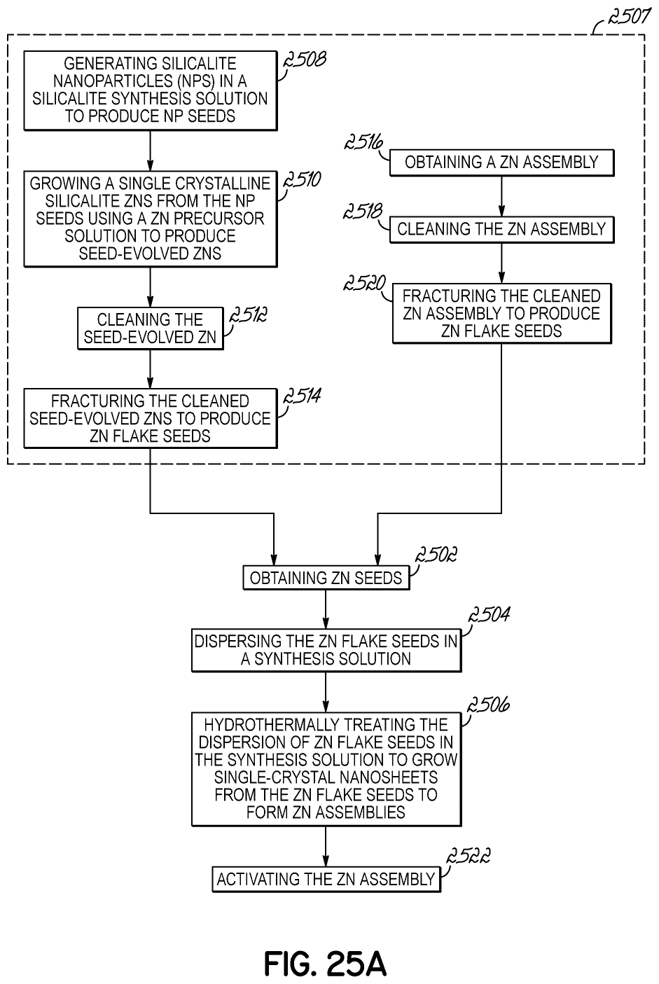

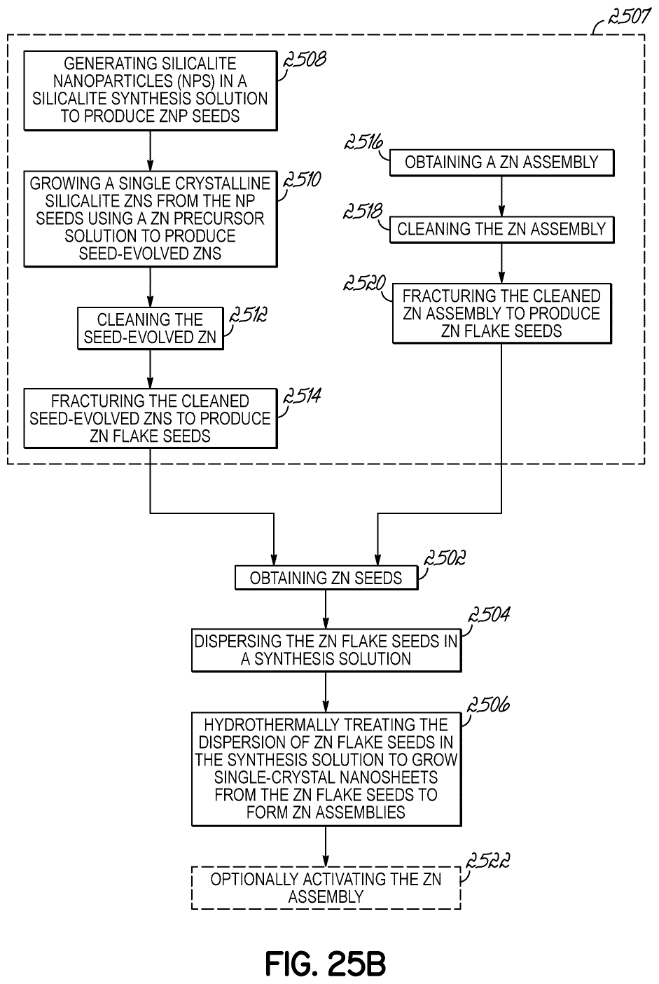

With reference to FIGS. 25A and 25B, a method 2500 for synthesizing ZN assemblies from ZN flake seeds is shown. This method includes a step 2502 for obtaining a ZN flake seeds, a step 2504 for dispersing the ZN flake seeds in a synthesis solution, and a step 2506 for hydrothermally treating the dispersion of ZN flake seeds in the synthesis solution to grow single-crystal nanosheets from the ZN flake seeds to form ZN assemblies. Step 2502 for obtaining the ZN flake seeds may optionally be preceded by a one or more process 2507 for producing the ZN flake seeds. In one such embodiment, producing the ZN flake seeds includes a step 2508 for generating silicalite nanoparticles (NPs) in a silicalite synthesis solution to produce NP seeds, a step 2510 for growing single crystalline silicalite ZNs from the NP seeds using a ZN precursor solution to produce seed-evolved ZNs, a step 2512 for cleaning the seed-evolved ZNs, and a step 2514 for fracturing the cleaned seed-evolved ZNs to produce ZN flake seeds. In an alternate embodiment, producing the ZN flake seeds includes a step 2516 for obtaining a ZN assembly, a step 2518 for cleaning the ZN assembly, and a step 2520 for fracturing the cleaned ZN assembly to produce ZN flake seeds. In another alternate embodiment, producing the ZN flake seeds includes the steps 2508 through steps 2514 and the steps 2516 through 2520. The method 2500 may further include a step 2522 for activating the ZN assembly. With reference to the embodiment of FIG. 25A, step 2522 for activating the ZN assembly is not optional. With reference to the embodiment of FIG. 25B, step 2522 for activating the ZN assembly is optional.

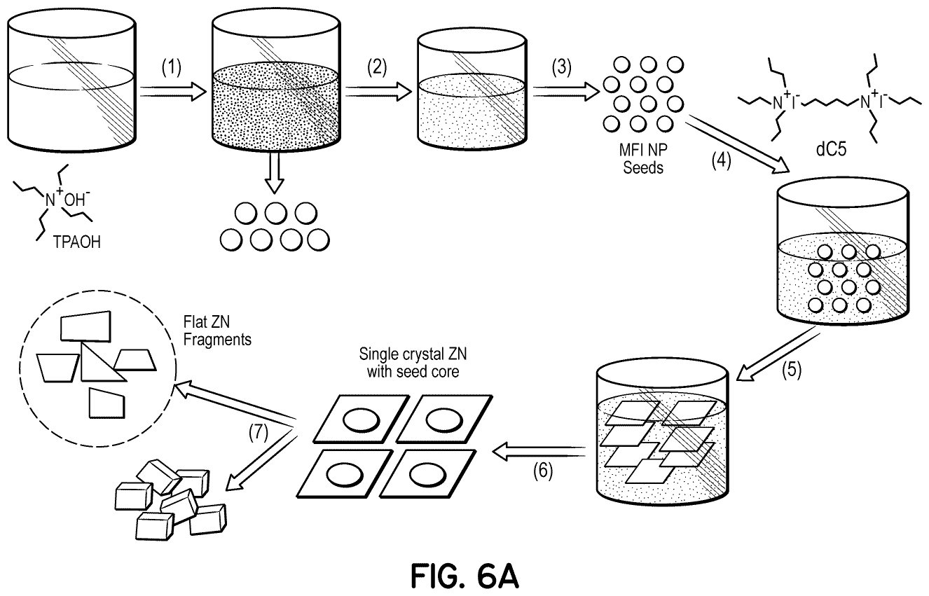

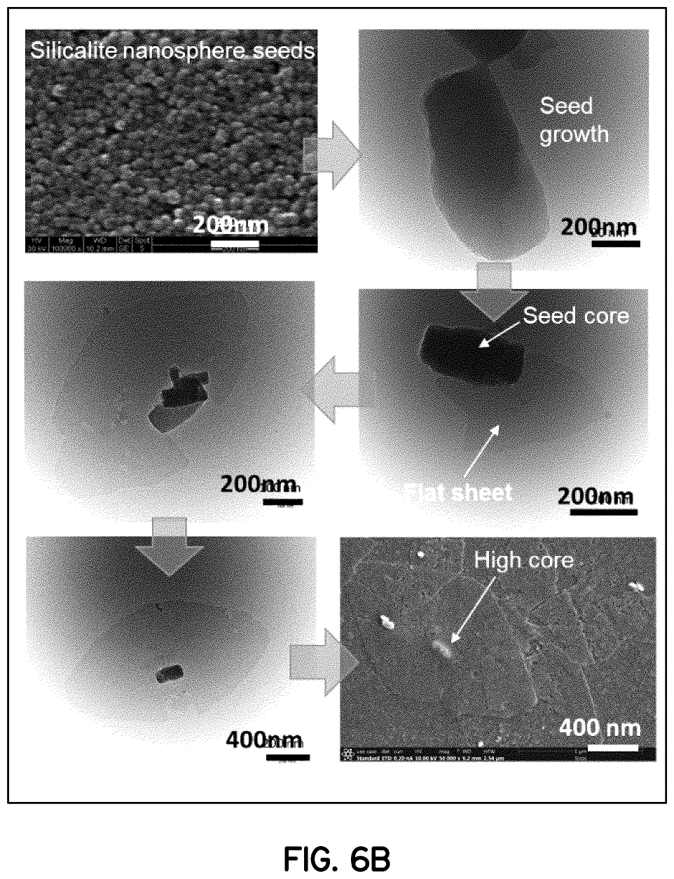

The pure-silica MFI (silicalite) ZNs used as ZN flake seeds for growing the first-generation ZN-assemblies may be synthesized by fracturing the seed-evolved ZNs produced according to the method reported by Jeon et al., Ultra-selective high-flux membranes from directly synthesized zeolite nanosheets, Nature. 543 (2017) 690-694. These seed-evolved ZNs were obtained by two separate steps of hydrothermal reactions. The first step was to generate silicalite nanoparticles (NP) seeds using a silicalite synthesis solution including an SDA, a source of silica, a solvent, and a base. The second step was to grow single crystalline silicalite zeolite nanosheets (ZNs) by mixing NP seeds and a ZN precursor solution including an SDA, a source of silica, a solvent, and a base. The detailed synthesis procedure is schematically depicted in FIGS. 6A and 6B together with microscopic images revealing the mechanism of NP-seeded ZN growth. Thus-synthesized zeolite ZN crystals (i.e., seed-evolved ZNs) generally include a NP seed core which functions as a substrate from which a ZN portion can be formed via secondary growth. The ZN portion, generally speaking, is a predominantly planar portion that is rhombus-shaped that surrounds the seed core and has a uniform thickness. In one embodiment, the thickness of the ZN portion is between 3-5 nm. In an alternate embodiment, the thickness of the ZN portion is roughly 4 nm. These seed-evolved ZNs, which are single crystalline silicalites grown on the NP seed substrate, may then be subjected to mechanical force sufficient to remove and/or separate the ZN portion from the NP substrate to serve as ZN flake seeds. Further mechanical force may optionally be applied to the ZN flake seeds to reduce the size of the ZN flake seeds. These ZN flake seeds may then be subjected to further hydrothermal treatment in the presence of a synthesis solution to synthesize a first-generation ZN-assembly.

With regard to generating ZNP seeds, the SDA may include, for example, tetrapropylammonium hydroxide (TPAOH), tetrapropylammonium bromide (TPABr), other suitable SDAs, or a combination thereof. In one embodiment, the SDA is TPAOH. The source of silica may include, for example, silica dioxide (SiO₂), tetraethyl orthosilicate (TEOS), aluminosilicates, some other suitable source of silica, or some combination thereof. In one embodiment, the source of silica is SiO₂. The solvent may include, for example, water, some other polar solvent, or some combination thereof. The base may include, for example, a hydroxide, ammonia, some other suitable base, or some combination thereof. In one embodiment, the base is a hydroxide. The base may be included in an amount to achieve a target pH. In one embodiment, the target pH is 13. In one embodiment, the molar ratio of the reagents is 10 SDA:2.4 source of silica:0.87 hydroxide:114 water. In a further embodiment, the SDA is TPAOH and the source of silica is SiO₂.

The synthesis of NP seeds may involve agitating the reagents for a period of time using means such as, for example, stirring, sonicating, other suitable means of mixing or agitating the reagents, or some combination thereof. The period of time for agitating the reagents may be greater than or equal to 1 hour, alternatively greater than or equal to 6 hours, or still alternatively greater than or equal to 12 hours. The stirring or agitation make take place at room temperature. Following agitation of the reagents for a defined period of time, the method of synthesizing NP seeds may include heating the reagents for a period of time. The period of time for heating the reagents may be greater than or equal to 8 hours, alternatively greater than or equal to 24 hours, still alternatively greater than or equal to 72 hours, or yet still alternatively greater than or equal to 144 hours. The period of time for heating the reagents may depend on the elevated temperature the reagents are heated to. For example, the reagents may be heated to a temperature greater than or equal to 50° C., alternatively a temperature greater than or equal to 100° C., or still alternatively a temperature greater than or equal to 140° C. Suitable methods for heating the reagents include, for example, an oil bath, a water bath, an oven, other suitable heating methods, or some combination thereof. In one embodiment, the reagents are heated without stirring.

Following heating the NP seed reagents for a period of time, the solution may be filtered and the filtrate subjected to additional heating for a period of time. The filtration may involve the use of a filter such as, for example, syringe filtration, column filtration, membrane filtration, vacuum filtration, some other suitable filtration technique, or some combination thereof. The period of time for heating the filtrate may be greater than or equal to 8 hours, alternatively greater than or equal to 24 hours, or still alternatively greater than or equal to 72 hours. The period of time for heating the filtrate may depend on the elevated temperature the filtrate is heated to. Heating the filtrate for a period of time may involve heating the filtrate to a temperature greater than or equal to 50° C., alternatively a temperature greater than or equal to 65° C., or still alternatively a temperature greater than or equal to 90° C. Suitable methods for heating the filtrate include, for example, an oil bath, a water bath, an oven, other suitable heating methods, or some combination thereof. In one embodiment, the filtrate is heated without stirring.

Following heating the filtrate for a period of time, the NP seed crystals may be washed using a solvent such as, for example, de-ionized (DI) water. This washing step may include a plurality of rinse steps and centrifugation steps to remove the supernatant liquid.

With regard to synthesizing single crystalline silicate ZNs, NP seeds are mixed with a ZN precursor solution. The NP seeds may include a NP synthesized using the method described above, another suitable ZNP, or some combination thereof. In one embodiment, the NP seeds are dispersed in solution, such as water, prior to mixing with the ZN precursor solution. With regard to the ZN precursor solution, the SDA may include, for example, dC5, diquaternary ammonium compounds, some other suitable SDA, or some combination thereof. In one embodiment, the SDA is dC5. The source of silica may include, for example, tetramethyl orthosilicate (TMOS), tetraethyl orthosilicate (TEOS), tetrapropyl orthosilicate (TPrOS), tetrabutyl orthosilicate (TBOS), tetrapentyl orthosilicate (TPeOS), tetrahexyl orthosilicate (THOS), aluminosilicates, fumed silica, some other suitable source of silica, or some combination thereof. In one embodiment, the source of silica is TEOS. The solvent may include, for example, water, some other polar solvent, or some combination thereof. The base may include, for example, a hydroxide, ammonia, some other suitable base, or some combination thereof. In one embodiment, the base includes a hydroxide such as, for example, sodium hydroxide, potassium hydroxide, some other hydroxide containing salt, or some combination thereof. In one embodiment, the molar ratio of the reagents in the ZN precursor solution is 3.75 SDA:80 source of silica:20 hydroxide:9500 water. In a further embodiment, the SDA is dC5 and the source of silica is TEOS.

The ZN precursor solution may be hydrolyzed prior to synthesis of the ZNs for a period of time. In one embodiment, hydrolyzation includes air purging of approximately 50 m/min at room temperature. The period of time for hydrolysis may be greater than or equal to 1 hour, alternatively greater than or equal to 4 hours, or still alternatively greater than or equal to 16 hours. In embodiments where the source of silica is an orthosilicate (e.g., TMOS, TEOS, etc.), hydrolysis may reduce the concentration of alcohols in the ZN precursor solution. In one such embodiment, the hydrolysis is a gas-purged hydrolysis.

Following hydrolysis of the ZN precursor solution, the ZN precursor solution may be subjected to filtration and the filtrate mixed with a solution including a dispersion of NP seeds to form seed-evolved ZNs. The filtration may involve the use of a filter such as, for example, syringe filtration, column filtration, membrane filtration, some other suitable filtration technique, or some combination thereof. In one embodiment, the solution is syringe filtered through a GHP (polypropylene) filter with a pore size smaller than or equal to 0.45 μm. The molar ratio of silica between the NP seed dispersion and the ZN precursor solution may be greater than or equal to 50, alternatively greater than or equal to 200, or still alternatively greater than or equal to 50 and less than or equal to 1000. After mixing the NP seed dispersion solution and the ZN precursor solution, the mixture may be subjected to hydrothermal treatment for a period of time to form seed-evolved ZNs. In one such embodiment, hydrothermal treatment of the mixture includes heating the mixture to a temperature greater than or equal to 140° C. in an autoclave for a period of time. The period of time may be greater than or equal to 36 hours, alternatively greater than or equal to 36 hours and less than or equal to 96 hours, or still alternatively greater than or equal to 96 hours.

Depending on factors such as, for example, the period of time for hydrothermal treatment, more or less amorphous silica may be formed along with the seed-evolved ZNs. Generally speaking, lower hydrothermal treatment times results in a higher amount of amorphous silica formed. Additionally, the seed-evolved ZNs may include one or more organic residue adsorbed onto the zeolite. In embodiments where a non-negligible amount of amorphous silica is formed and/or organic residues remain on the seed-evolved ZNs, the hydrothermal treatment step may be followed by an optional base treatment. The optional base treatment may include, for example, mixing equal volumes of a dispersion containing the seed-evolved ZNs with a base solution having 0.1 M hydroxide ions (e.g., from a hydroxide salt such as potassium hydroxide, sodium hydroxide, etc.) to form a base treatment mixture and centrifuging the base treatment mixture to recover the ZN products. In one embodiment, the volume of the dispersion containing the seed-evolved ZNs and the volume of the base solution are each 1 mL. Depending on the amount of amorphous silica formed, the above base treatment steps may be repeated as needed until a white slurry including the seed-evolved ZNs can be obtained following centrifugation. In one embodiment, the above base treatment steps are repeated one time, alternatively greater than or equal to one time.

Following the above optional base treatment steps or as an alternative to the above optional base treatment steps, the white slurry containing the seed-evolved ZNs may be subjected to an optional base-chloride treatment step. In an optional base-chloride treatment step, the seed-evolved ZNs may be dispersed in a base-chloride cleaning solution having a volume approximately equal to the base treatment mixture. In one embodiment, the volume of the base-chloride cleaning solution may be 2 mL. This cleaning process may improve the usefulness of seed-evolved ZNs formed at least by removing the amorphous silica and organic residues adsorbed on ZN surfaces, which could shield the active nucleation sites, and by cleaving surface Si—O—Si that could create [≡Si—O(—)] sites to induce nucleation in different orientations in subsequent steps. In one embodiment, the base-chloride solution has 0.1 M hydroxide ions and 1 M chloride ions (e.g., potassium chloride, etc.), or alternatively 0.1 M hydroxide ions and 2 M chloride ions. In one embodiment, the base solution and the base chloride solution are made using hydroxide salts and chloride salts having the same cation. The dispersion of the white slurry containing the seed-evolved ZNs in the base-chloride cleaning solution may be stirred at room temperature for a period of time greater than or equal to 8 hours, alternatively greater than or equal to 24 hours, still alternatively greater than or equal to 72 hours, or yet alternatively greater than or equal to 168 hours. In some embodiments, such as those embodiments with longer treatment times with the base-chloride cleaning solution (e.g., greater than or equal to 72 hours), the base-chloride cleaning solution may be replaced with a fresh base-chloride cleaning solution one or more time. Following this dissolution step in the base-chloride cleaning solution, the seed-evolved ZNs may washed with DI water one or more time.

The seed-evolved ZNs, which may be formed according to the steps above, may then then be subjected to mechanical force sufficient to fracture and/or separate the ZN portion from the NP seed core. Applying a mechanical force may include methods such as, for example, milling, sonication, sonicated ball-milling, other suitable methods of applying mechanical force, or some combination thereof. In one embodiment, fracturing the seed-evolved ZNs includes sonicated ball milling in a solvent. In one such embodiment, the seed-evolved ZNs are dispersed in water for sonicated ball milling. In another such embodiment, the solution for sonicated ball milling is ethanol. Water may be used as a solvent in applications where the fractured ZN portions are later used as ZN flake seeds. Ethanol may be used as a solvent where the fractured ZN portions are ZN plates later used to tile a polymer substrate or a polymer membrane (discussed further below). The fractured flat ZN fragments (i.e., ZN flakes), which can be used as ZN seeds (i.e., ZN flake seeds) as discussed further below, were separated from the large core debris by one or more fractionation and rinse steps. The fractionation step may include at least one of centrifugation, filtration, sedimentation, some other suitable fractionation technique, or some combination thereof. Fractionation and rinsing may be followed by further ball-milling to generate smaller ZN flake seeds for greater seed population.

These ZN fragments may then be used as ZN flake seeds. In one embodiment, the ZN flake seeds may be subsequently dispersed in a synthesis solution including a source of silica, an SDA, a solvent, and a base. The SDA may include, for example, dC5, diquaternary ammonium compounds, some other suitable SDA, or some combination thereof. In one embodiment, the SDA is dC5. The source of silica may include, for example, tetramethyl orthosilicate (TMOS), tetraethyl orthosilicate (TEOS), tetrapropyl orthosilicate (TPrOS), tetrabutyl orthosilicate (TBOS), tetrapentyl orthosilicate (TPeOS), tetrahexyl orthosilicate (THOS), fumed silica, aluminosilicates, some other suitable source of silica, or some combination thereof. In one embodiment, the source of silica is TEOS. The solvent may include, for example, water, some other polar solvent, or some combination thereof. The base may include, for example, a hydroxide, ammonia, some other suitable base, or some combination thereof. In one embodiment, the base includes a hydroxide such as, for example, sodium hydroxide, potassium hydroxide, some other hydroxide containing salt, or some combination thereof. In one embodiment, the synthesis solution had a molar ratio of components equal to 80 source of silica:3.75 SDA:20 hydroxide:12000 H₂O to avoid undesirable nucleation and inhibit random growth. In a further embodiment, the source of silica is TEOS and the SDA is dC5. The mass ratio of silica between the ZN seeds and the source of silica in the precursor solution may be greater than or equal to 500, alternatively greater than or equal to 1000, or still alternatively greater than or equal to 2000.

The mixture of ZN flake-seeds and synthesis solution may then be subjected to hydrothermal treatment for a period of time to obtain a first-generation ZN-assembly. Generally speaking, the ZN seeds may function as a substrate from which secondary growth using the synthesis solution may occur. In one embodiment, the mixture of ZN seeds and synthesis solution are placed in an autoclave for autogenous reaction at 140° C. The period of time for hydrothermal treatment of the ZN seeds and the synthesis solution may be greater than or equal to 24 hours, alternatively greater than or equal to 96 hours, or still alternatively greater than or equal to 96 hours and less than or equal to 144 hours. After the hydrothermal treatment, the first-generation ZN-assemblies were separated by centrifuge and then thoroughly cleaned using a hydroxide cleaning solution. Following this cleaning, the first-generation ZN-assembly may be dried and characterized.

The reaction conditions used to synthesize the ZN assemblies may impact the structure of the ZN assemblies formed. In one embodiment, the ZN assembly has a predominantly planar structure and comprises multiple single-crystal ZN layers to form a ZN plate. The ZN plate may have a thickness expressed in ZN layers such as greater than or equal to 2 single-crystal ZN layers, alternatively greater than or equal to 10 single-crystal ZN layers, or still alternatively greater than or equal to 2 single-crystal ZN layers and less than or equal to 20 single-crystal ZN layers. In another embodiment, the first-generation ZN assembly formed had multiple intersecting planar structures that resembled a flower such as, for example, a rose-like structure or a spiral leaf-like structure. In a further embodiment, the flower-like structure may be comprised of one or more orthogonal ZN plate.

In some embodiments, an optional secondary cation addition step may be implemented during thermal treatment of the ZN-seeds and precursor solution to form a ZN-material incorporating isomorphous substitutes. In such embodiments, a source of one or more optional secondary element, such as a metal salt containing an optional secondary metal, may be dissolved or dispersed in water, the solution or dispersion including the one or more optional secondary metal may be mixed added to the mixture of ZN-seeds and precursor solution, and the resulting mixture may be subjected to hydrothermal treatment for a period of time. The solution or dispersion of the one or more optional secondary metal may be prepared or selected such that the atomic ratio of silicon to secondary metal(s) in the resulting ZN-material is greater than or equal to 1:1. The secondary metal may include, for example, aluminum, boron, tungsten, other suitable metals, or some combination thereof. In one embodiment, aluminum is included as a secondary framework metal ion from a sodium aluminate dissolved in a solution. The period of time for hydrothermal treatment of the mixture after introducing the optional secondary metal may be greater than or equal to 12 hours, or alternatively greater than or equal to 12 hours and less than or equal to 36 hours. It should be understood that further references to first-generation ZN assemblies may refer to embodiments incorporating one or more secondary metal as described above.

First-generation ZN assemblies, such as those formed using the method steps detailed above, may then be subjected to mechanical force sufficient to form ZN fragments which can serve as ZN flake seeds. Applying mechanical force sufficient to form ZN fragments may include methods such as, for example, milling, sonication, sonicated ball-milling, other suitable methods of applying mechanical force, or some combination thereof. In one embodiment, fracturing the ZN assemblies includes sonicated ball milling in a solvent. In one such embodiment, the ZN assemblies are dispersed in water for sonicated ball milling. In another such embodiment, the solution for sonicated ball milling is ethanol. Water may be used as a solvent in applications where the ZN fragments are later used as ZN flake seeds. Ethanol may be used as a solvent where the ZN fragments are ZN plates later used to tile a polymer substrate or a polymer membrane (discussed further below). These ZN fragments may be used as ZN flake seeds instead of or in addition to the NP seeds and/or the ZN flake seeds formed from fracturing the NP seed-evolved ZNs. The ZN seeds are mixed with a synthesis solution containing an SDA, a source of silica, a solvent, and a base. The SDA may include, for example, dC5, diquaternary ammonium compounds, some other suitable SDA, or some combination thereof. In one embodiment, the SDA is dC5. The source of silica may include, for example, tetramethyl orthosilicate (TMOS), tetraethyl orthosilicate (TEOS), tetrapropyl orthosilicate (TPrOS), tetrabutyl orthosilicate (TBOS), tetrapentyl orthosilicate (TPeOS), tetrahexyl orthosilicate (THOS), aluminosilicates, fumed silica, some other suitable source of silica, or some combination thereof. In one embodiment, the source of silica is TEOS. The solvent may include, for example, water, some other polar solvent, or some combination thereof. The base may include, for example, a hydroxide, ammonia, some other suitable base, or some combination thereof. In one embodiment, the base includes a hydroxide such as, for example, sodium hydroxide, potassium hydroxide, some other hydroxide containing salt, or some combination thereof. In one embodiment, the synthesis solution had a molar ratio of components equal to 80 source of silica:3.75 SDA:20 hydroxide:12000 H₂O to avoid undesirable nucleation and inhibit random growth. In a further embodiment, the source of silica is TEOS and the SDA is dC5. The mass ratio of silica between the ZN seeds and the source of silica in the precursor solution may be greater than or equal to 500, alternatively greater than or equal to 1000, or still alternatively greater than or equal to 2000. In one embodiment, the synthesis solution for the ZN seeds formed from first-generation ZN assemblies contains the same components in the same ratio as the synthesis solution for the ZN seeds formed from the NP seed-evolved ZNs.

The mixture of the ZN flake seeds formed from fracturing the first-generation ZN assembly fragments and the synthesis solution may be subjected to hydrothermal treatment for a period of time to form a second-generation ZN assembly. Generally speaking, the ZN seeds may function as a substrate from which secondary growth using the synthesis solution may occur. In one embodiment, the mixture of ZN seeds and synthesis solution are placed in an autoclave for autogenous reaction at 140° C. The period of time for hydrothermal treatment of the ZN flake seeds and the synthesis solution may be greater than or equal to 24 hours, alternatively greater than or equal to 96 hours, or still alternatively greater than or equal to 96 hours and less than or equal to 144 hours. After the hydrothermal treatment, the second-generation ZN-assemblies may be separated by centrifuge and then thoroughly cleaned using a hydroxide cleaning solution as discussed above. Following this cleaning, the second-generation ZN-assembly may be dried and characterized.

It should be understood that the method for obtaining a second-generation ZN assembly from a first-generation ZN assembly may be adapted to obtain a third-generation ZN assembly from a second-generation ZN assembly using similar steps, to obtain a fourth-generation ZN assembly from a third-generation ZN assembly using similar steps, and so on. In one embodiment, forming a second-generation or later ZN assembly (hereinafter a higher-generation ZN assembly) may use ZN fragments (i.e., ZN flake seeds) from only the preceding ZN assembly generation. In an alternate embodiment, forming a higher-generation ZN assembly may use ZN fragments from one or more previous generation ZN assembly (e.g., a third-generation ZN assembly may use ZN fragments from both first-generation and second-generation ZN assemblies). In yet another alternate embodiment, forming a higher-generation ZN assembly may use ZN fragments from the NP seed-evolved ZN and one or more previous generation ZN assembly. A major difference between forming the first-generation ZN assemblies and forming second-generation ZN assemblies and onwards is that the ZN seeds for second-generation ZN-assemblies and onwards may simply include the ZN fragments of one or more of the prior generation ZN assemblies. Put differently, formation of higher-generation ZN assemblies may allow for formation of ZN seeds without requiring further synthesis of NP seeds or NP seed-evolved ZNs.

Any of the ZN assemblies described above (i.e., first-generation ZN assemblies and higher-generation ZN assemblies) may be activated. In one embodiment, the ZN assembly may be activated by subjecting the ZN assembly to air at an elevated temperature for a period of time to calcinate the ZN assembly. Calcination may function to remove the SDA, such as dC5, from the zeolite pores to activate the zeolite without collapsing the structure of the ZN assembly. The elevated temperature may be greater than 400° C., alternatively greater than or equal to 500° C., or still alternatively greater than or equal to 600° C. The elevated temperature may be reached by gradually increasing the temperature of the environment. In one such embodiment, the temperature is increased at a rate of less than or equal to 5° C./min. The period of time for calcination may be greater than or equal to 3 hours, or alternatively greater than or equal to 6 hours. Following calcination, the temperature of the environment may be gradually reduced. In one such embodiment, the temperature following calcination is reduced at a rate of less than or equal to 5° C./min.

After calcination, the ZN assemblies may be subjected to dissociation or fracturing in liquid solvent to produce dispersed open-pore ZN plates for tiling a membrane on a polymer support. The dissociation or fracturing to form ZN plates may include, for example, sonication, milling, sonicated ball-milling, some other means of fracturing a zeolite, or some combination thereof. In one embodiment, fracturing the ZN assemblies includes sonicated ball milling in a solvent. In one such embodiment, the ZN assemblies are dispersed in water for sonicated ball milling. In another such embodiment, the solution for sonicated ball milling is ethanol. Ethanol may be used as a solvent where the ZN plates are later used to tile a polymer substrate or a polymer membrane. In one such embodiment, the calcined ZN assembly is fractured using sonicated ball milling in an ethanol bath. The ZN plates dissociated or fractured from the ZN assembly may be mixed with smaller ZN fragments. Larger ZN plates may be separated from ZN fragments using a fractionation technique including, for example, sedimentation, filtration, centrifugation, some other means of fractionating solids based on size, or some combination thereof.

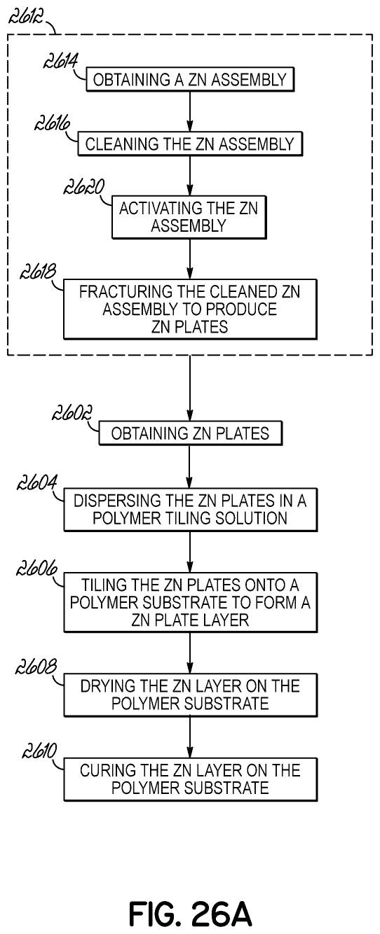

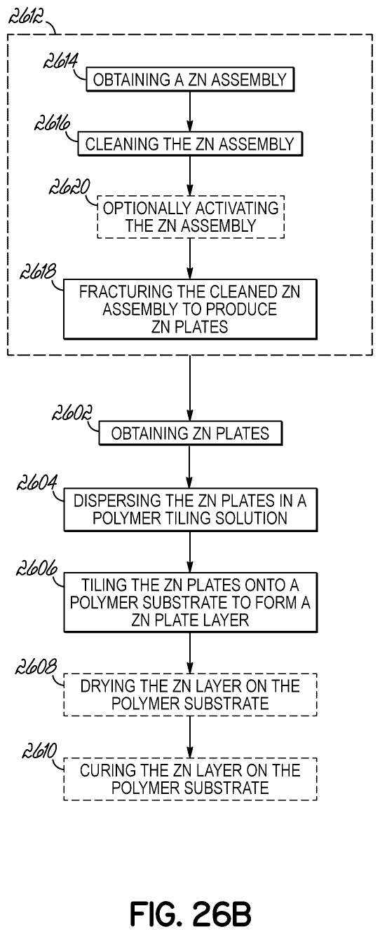

With regard to FIGS. 26A and 26B, a method 2600 for tiling a polymer substrate with ZN plates is shown. The method 2600 includes a step 2602 for obtaining the ZN plates, a step 2604 for dispersing the ZN plates in a polymer tiling solution, and a step 2606 for tiling the ZN plate dispersion onto a polymer substrate. With respect to FIG. 26B, the method 2600 may optionally further include an optional step 2608 for drying the ZN plates on the polymer substrate after step 2606 and an optional step 2610 for curing the ZN plates on the polymer substrate after the optional step 2608. With further reference to FIGS. 26A and 26B, the step 2602 for obtaining the ZN plates may be preceded by an optional process 2612 for producing the open-pore ZN plates. In one such embodiment, the optional process 2612 comprises a step 2614 for obtaining a ZN assembly, a step 2616 for cleaning the ZN assembly, and a step 2618 for fracturing the ZN assembly to produce ZN plates. Optionally, the process 2612 may include a step 2620 for activating the ZN assembly prior to fracturing the ZN assembly. With reference to FIG. 26A, step 2620 is not optional for the process 2612. With reference to the embodiment of FIG. 26B, step 2620 is optional within the process 2612. In a further embodiment, step 2614 comprises synthesizing a ZN assembly according to method 2500 shown in FIG. 25.

Preactivated ZN plates may be used for tiling on a polymer substrate to form a ZN plate-tiled (ZNPT) membrane. The polymer substrate may include a material such as, for example, polyethylene (PE), polypropylene (PP), polyvinylidene fluoride (PVDF), polysulfone, polyacrylonitrile (PAN), Polytetrafluoroethylene (PTFE), Nafion®, other suitable polymer substrates, or some combination thereof. In one embodiment, the polymer substrate may be porous. Tiling a polymer substrate with the ZN plates may involve dispersing the ZN plates in a polymer tiling solution including a solvent, an amount of dissolved polymer binders, and a binder solvent. The solvent may be an organic solvent, such as ethanol, isopropanol, some other organic solvent, or some combination thereof. In one embodiment, the solvent is configured to be miscible with the binder solvent but not to dissolve the polymer binder. The polymer binder dissolved in the polymer tiling solution may function as adhesive for the polymer substrate and the ZN plates. The polymer binder may include, for example, polyethylene (PE), polypropylene (PP), polyvinylidene fluoride (PVDF), polysulfone, polyacrylonitrile (PAN), Polytetrafluoroethylene (PTFE), Nafion®, other suitable nonionic and ionic polymers, or some combination thereof. In one such embodiment, the polymer binder dissolved in the polymer tiling solution comprises the same materials as the polymer substrate. In one embodiment, the binder solvent is dimethyl sulfoxide (DMSO). The polymer binder may first be dissolved in the binder solvent before adding the solvent. In one such embodiment, the binder solvent DMSO is used to dissolve a PVDF polymer binder prior to adding an amount of the solvent, which is an organic solvent, for controlling ZN plate content in suspension. The ratio of solvent to the binder solvent may be selected to be high enough to ensure that the polymer binder completely dissolves and low enough that the polymer substrate surface is not damaged during the membrane coating process (discussed further below). In one such embodiment, the weight ratio of solvent to the binder solvent is 2:1. In a further embodiment, the solvent is an organic solvent and the binder solvent is DMSO. In an even further embodiment, the organic solvent is ethanol and the weight ratio of ethanol to DMSO is 2:1. The weight percentage of the ZN plates dispersed in the tiling solution may be selected to high enough to minimize uncovered spots or pinholes in the ZN plate layer and low enough to minimize defects from misaligned ZN plates. In one such embodiment, the weight percentage of ZN plates in solution is greater than or equal to 0.01 wt. %, alternatively greater than or equal to 0.02 wt. %, or still alternatively greater than or equal to 0.01 wt. % and less than or equal to 0.06 wt. %. Alternatively, the weight percentage of ZN plates in solution may be less than or equal to 0.1 wt. %. Still alternatively, the weight percentage of ZN plates in solution may be less than or equal to 1 wt. %.

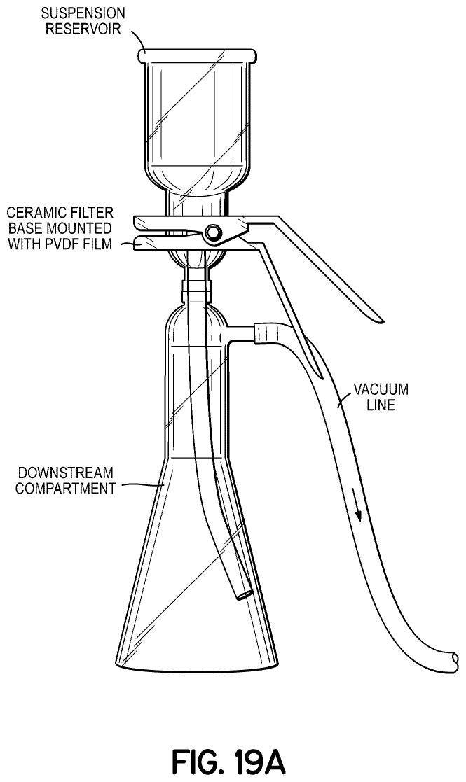

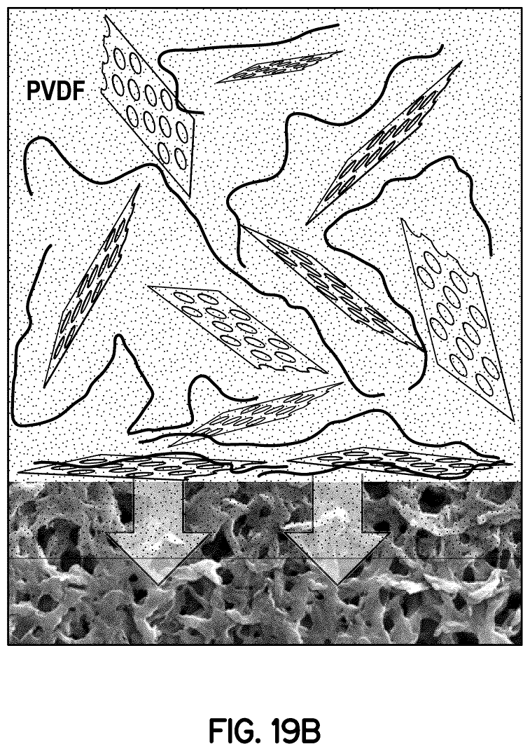

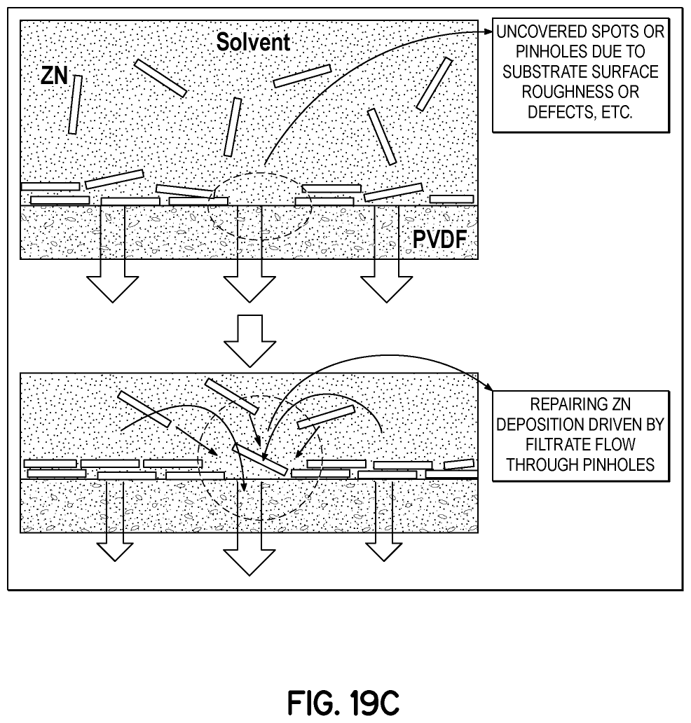

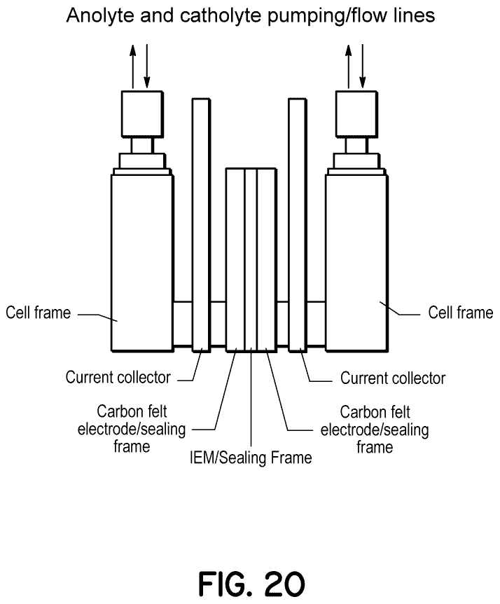

The ZN plates may be tiled on the polymer substrate by filtration coating using a pressure driving force for filtration such as, for example, downstream vacuum or upper stream pressurization. The vacuum may use a downstream pressure of less than or equal to 0.1 bar for a period of time to pull the polymer tiling solution through the polymer substrate. In one embodiment, the period of time for vacuum filtration to tile the polymer substrate is approximately 3 minutes. The polymer substrate may be presoaked with the solvent to avoid strong capillary suction when loading the polymer tiling solution which may result in misaligned ZN plate deposition. In one such embodiment, the solvent is an organic solvent. The polymer tiling solution may be deposited on top of the polymer substrate, and vacuum may be pulled to filter the polymer tiling solution through the polymer substrate, thereby tiling the polymer substrate with the ZN plates. In one such embodiment, the polymer substrate may be mounted to a ceramic filter between a suspension reservoir and a downstream compartment, the polymer tiling solution may be deposited into the suspension reservoir on top of the polymer substrate, and vacuum may be pulled through a vacuum line to filter the polymer tiling solution from the suspension reservoir through the polymer substrate into the downstream compartment, thereby tiling the polymer substrate with the ZN plates (see FIG. 19A). During the coating process, the solvent filtrate flow generally diminishes at areas tiled with ZN plates, slowing down further deposition of ZN plates in these areas, while high filtrate flow continues at spots uncovered by ZN plates, resulting in an increased tiling rate at these uncovered portions (see FIG. 19B).

Following the vacuum filtration tiling process, the resulting ZNPT polymer substrate may be dried and/or cured. The temperatures for drying and curing depend on the type of polymer substrate, the type of binder, as well as the solvent(s) and/or binder solvent(s) used. In one embodiment, the ZNPT polymer substrate is dried at an elevated temperature under vacuum for a period of time. The drying process may involve a temperature greater than or equal to 80° C. for a period of time greater than or equal to 3 hours under a vacuum pressure of less than or equal to 1.5 kPa. In one embodiment, the ZNPT polymer substrate is cured at an elevated temperature under vacuum for a period of time. In a further embodiment, the ZNPT polymer substrate is cured after it is dried. The curing process may involve a temperature greater than or equal to 120° C. at a pressure less than or equal to 24 kPa for a period of time greater than or equal to 3 hours.

### EXAMPLES

### Characterization Methods

The morphological and microstructural characteristics of the ZN assemblies, ZN fragments, and other zeolite crystals of different growth stages were investigated by scanning electron microscopy (SEM) and energy dispersive X-ray spectroscopy (EDS) using a FEI Scios DualBeam microscope equipped with Ametek Octane Super EDAX.

The thicknesses of the ZN plates constituting the ZN-assemblies and the isolated single-crystalline ZN sheets were examined by a Veeco Dimension 3100 atomic force microscope (AFM) using height imaging/profiling under tapping mode.

The crystalline phase and orientation of the ZNs were identified by X-ray diffraction (XRD) using a PANalytical X'Pert Pro diffractometer with Cu Ku radiation (λ=1.5406 Å) and confirmed by transmission electron microscopy (TEM) and electron diffraction (ED) observations using a JEOL 2010F field emission electron microscope. The high-resolution TEM observations were also used to unveil the mechanisms of ZN-assembly formation and growth in the very early stages.

The XRD peak identification and crystal phase determination were based upon the standard spectrum of silicalite powders.

The porosity and surface area of the ZN-assemblies were examined by the N₂ adsorption-desorption isotherms using an Miromeritics ASAP 2020 BET unit.

The dynamic adsorption behaviors of p-xylene and o-xylene vapors on the ZN-assemblies were investigated at 300 K by a Cahn 1000 Microbalance. The zeolite sample was degassed at about 573.15 K for overnight before each adsorption test. The gas phase xylene vapor pressure was around 0.67 kPa (or p/pₒ approximately 0.5). The xylene adsorption data were used to analyze the accessibility of the micropores and mesopores in the ZN-assemblies. A sample of conventional silicalite crystals was also examined for xylene adsorption measurements for comparison.

### Example 1

### Methods

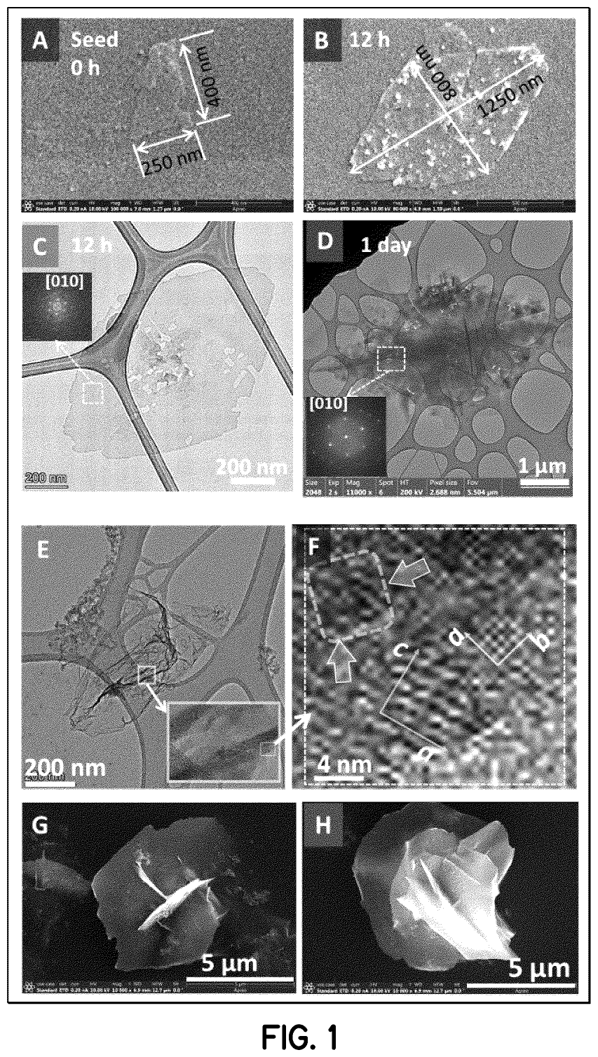

First-generation ZNs and ZN assemblies were grown from seeds consisting of single crystalline silicalite ZN flakes (i.e., ZN fragments) of submicron lateral lengths and 4-nm thickness in its b-axis (FIG. 1A). Lateral lengths and thicknesses for the ZN flake seeds were determined using SEM and/or TEM images. Depending on the seed population estimated from the SEM and/or TEM images, ball milling may optionally be used to fracture ZN flake seeds. The ball-milling of the ZN seeds not only increased the seed population for improving productivity but also created freshly fractured ZN edges containing highly energetic sites to induce secondary growth.

To investigate the secondary crystallization behavior of the ZN seeds, the solid products were retrieved after different reaction durations, which were microscopically analyzed. The reaction consisted of hydrothermal treatment of MFI ZN flake seeds dispersed in a synthesis solution and heated in an autoclave at 140° C. for a period of time. The synthesis solution included an SDA (dC5), a source of silica (TEOS), a solvent (water), and a base (potassium hydroxide) in a molar ratio of 3.75:80:20:12000. The period of time was varied to determine differences in synthesizing first-generation ZN assemblies at 12 hours, 24 hours, 48 hours, 72 hours, 96 hours, and 144 hours. The results of hydrothermal treatments for different periods of time were compared by analyzing samples using SEM images, TEM images, an AFM height survey.

### DISCUSSION

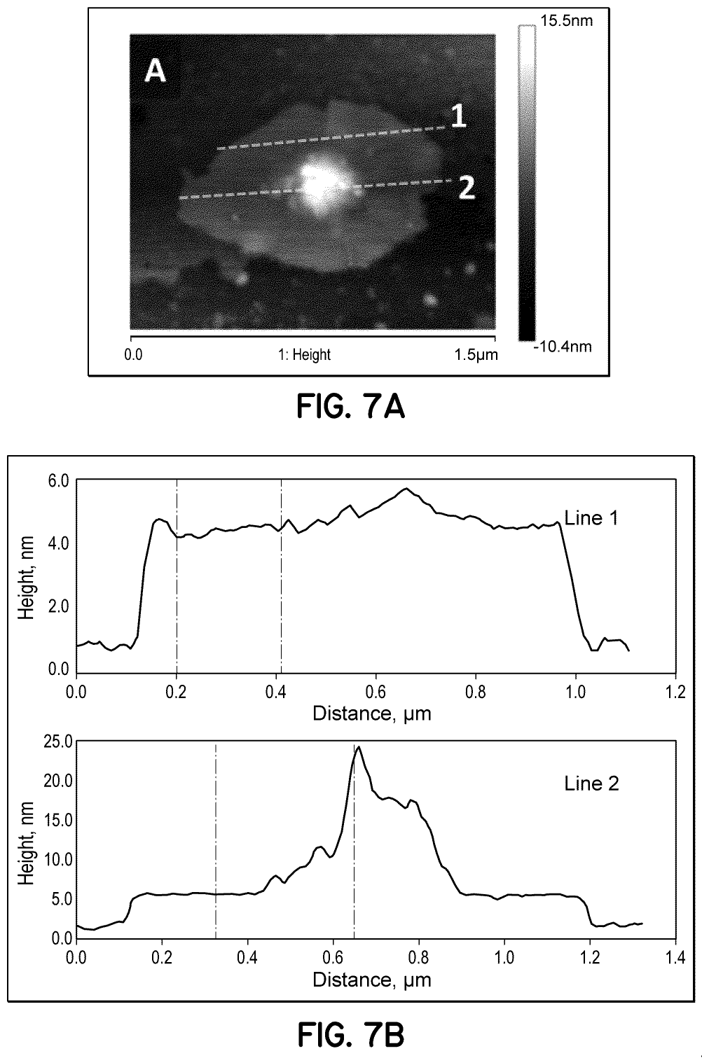

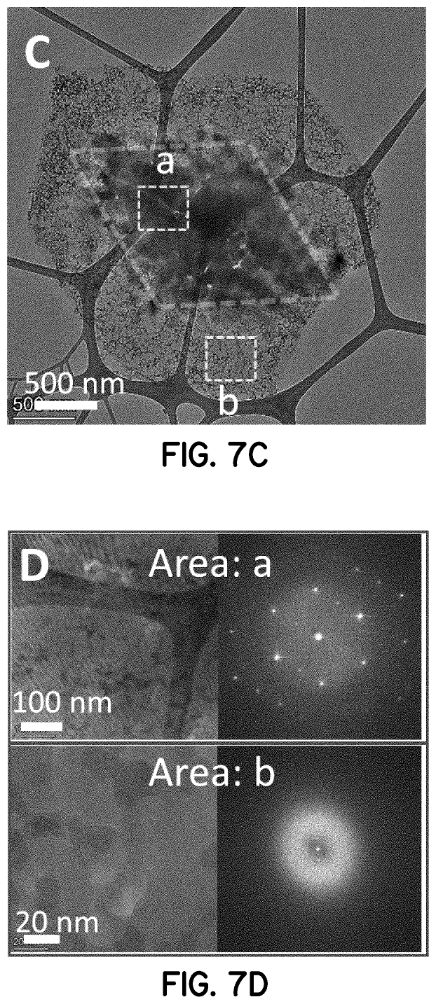

After reacting for 12 hours, the SEM and TEM images revealed that the ZN flake seeds, which had irregular shapes and sizes around approximately 0.1 μm² (FIG. 1A), grew into ZN sheets having a rhombus shapes and average areas of approximately 0.50 μm² (FIG. 1B). The rhombus sheets had a uniform thickness of approximately 4 nm (FIGS. 7A and 7B), that was the same as the ZN flake seeds. In this largely early-stage growth was largely epitaxial in a-c plane (same as the seed ZN) directed by the dC5 SDA. The SDA appears to inhibit growth in b-axis due to, at least in part, the strong stresses from the dimensional mismatch between inter-quaternary space (C5) of dC5 and neighboring intersection-distance of the MFI framework.

The AFM height survey revealed that the ZN seed seemingly formed a 10-20 nm tall central plateau in the premature rhombus sheet (FIGS. 7A and 7B). Large amounts of nanoparticles were observed in the product after the 12 hour reaction (FIG. 1B). These nanoparticles were determined to be largely amorphous silica and they could be readily dissolved in the KOH solution (FIGS. 7C and 7D). Similar nanoparticles were seen in literature during syntheses of MFI ZN with quaternary ammonium SDA and such particles were believed to be precursors for nucleation and crystal growth on seed surfaces. The rhombus sheet was further analyzed using TEM images and ED analysis to determine that the ZN sheet had a smooth surface with thickness along the [010](b-axis) direction (FIG. 1C).

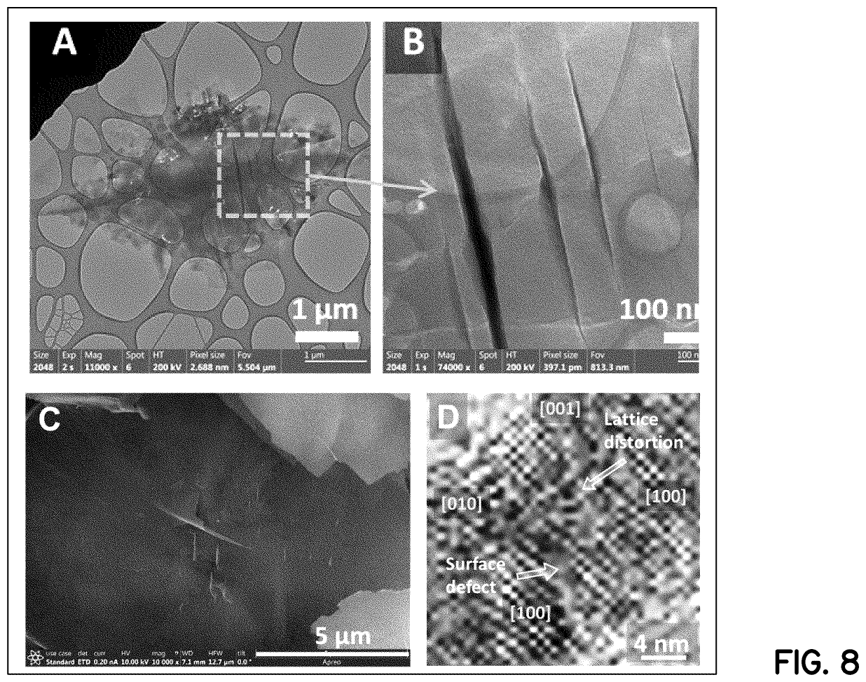

When the reaction duration was extended to 24 hours, TEM images showed that the ZN sheets further grew to rhombuses having an average size of approximately 7.5 μm² (FIG. 1D). When these larger ZN rhombus sheets were analyzed using a TEM, there were noticeable changes microstructure. Unlike the smooth-surfaced sheet after the 12-hour reaction, the rhombus sheet from the 24-hour reaction exhibited microscopic features of densely populated discrete nanoparticles and emerging ZNs in orientation orthogonal to the base ZN surface (FIGS. 8A and 8B). To examine the microscopic and crystalline structure of the rhombus sheet surface, the sample was treated by 1-week of sonication in a base treatment solution having 0.1 M KOH to eliminate amorphous particles and possible loosely attached nanocrystals. When the base treated ZN rhombus sheets were analyzed using a TEM image, intensively cleaned ZN fragments appeared to be free of particulate in the ZN surface (FIG. 1E). However, when reviewing the same samples using the high-resolution TEM, nanodomains of distorted lattice in the ZN surface and nuclei with a-c plane oriented normally to the seed surface (i.e., orthogonal growth from seed surface) were discovered (FIG. 1F). For example, the isolated domain of lattice in [010] direction likely reflected the a-c plane surface of the base ZN; and the nanodomain displaying [100] lattice structure showed a nucleus grown in rotated (orthogonal) orientation from the seed surface.

When the reaction duration was extended to 48 hours, SEM imaging revealed that the ZN rhombus sheets further developed orthogonal ZN plates (FIG. 1G). It appears that the [100]-oriented nuclei apparently initiated the growth of the orthogonal ZN plates.

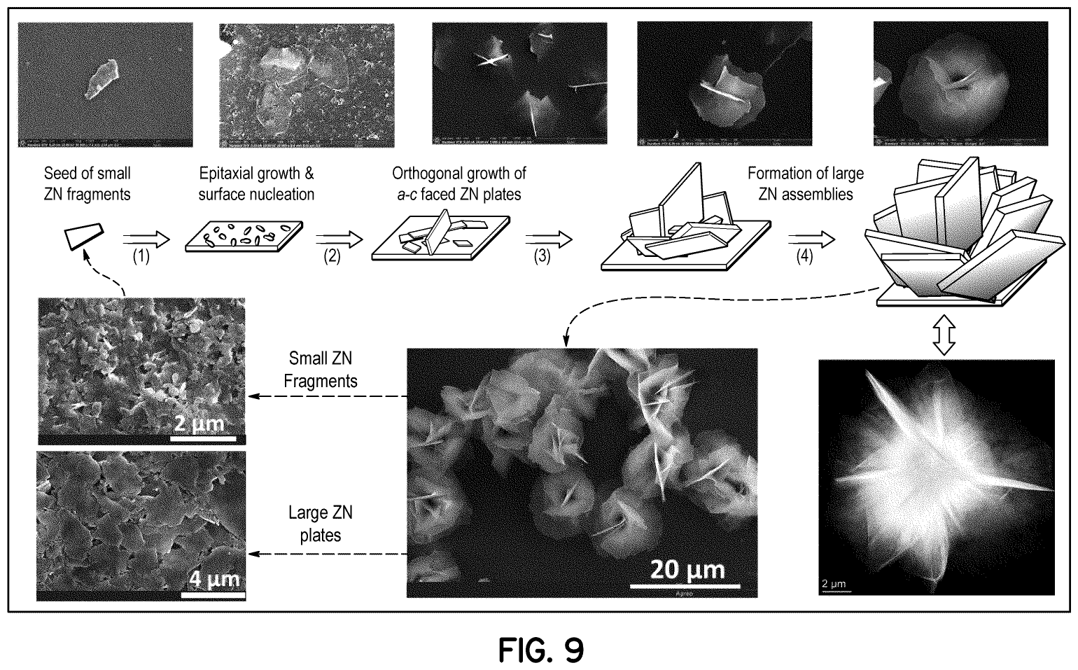

When the reaction duration was extended to 72 hours, more orthogonal ZN plates were formed and the orthogonal ZN plates were larger on average (FIG. 1H). The steps of ZN self-seeded nucleation, orthogonal ZN evolution, and the subsequent ZN epitaxial growth into the very large flower-like ZN assembly are schematically illustrated FIG. 9.

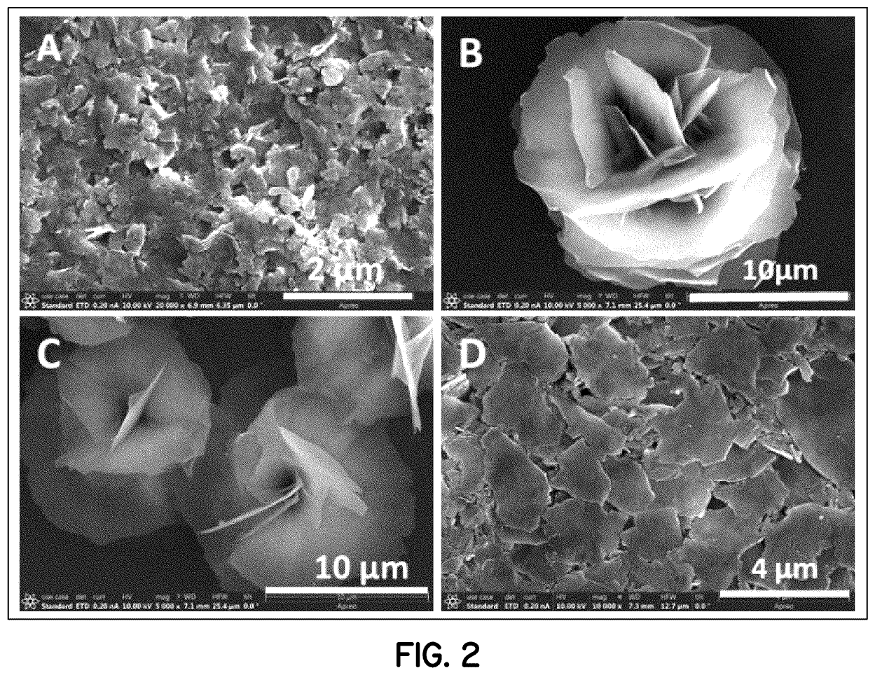

When the reaction duration was extended to 96 hours, the premature structures, e.g., the orthogonally-oriented ZN plates, and the amorphous nanoparticles seen in FIGS. 1G and 1H were no longer observed when analyzed using SEM images (FIG. 2). Further extension of the reaction duration to 144 hours caused no appreciable changes in structure and size of the ZN assemblies. Thus, the structural characterizations and material property analyses were performed for samples obtained after 96 hours of hydrothermal growth from the ZN flake seeds shown in FIG. 2A. The first-generation ZN assemblies obtained after 96 hours were analyzed using SEM images to determine that one of two distinct architectures were commonly formed. The first architecture included a plurality of ZN plates growing from the ZN flake seed wherein the ZN plates growing from the ZN flake seed resembled flower petals in a structure resembling a rose flower (hereinafter the rose flower structure) (FIG. 2B). The second architecture included a plurality of ZN plates resembling flower petals growing from the ZN flake seed in a structure resembling a spiral leaf (hereinafter the spiral leaf structure) (FIG. 2C). The flower-like assemblies had average overall diameters of less than or equal to 15 μm.

### Example 2

### Methods

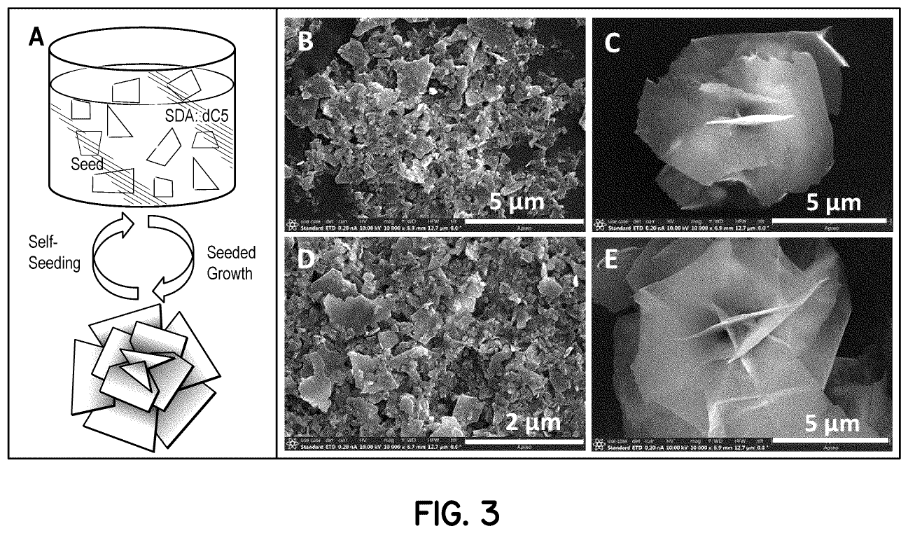

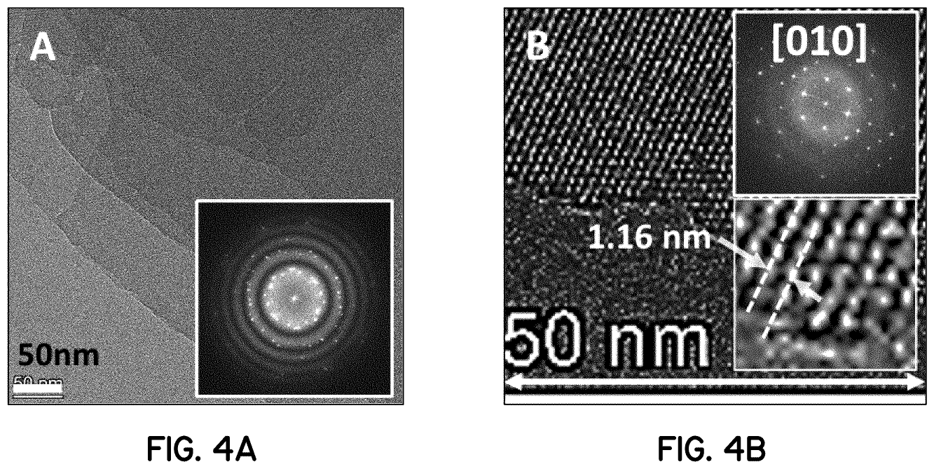

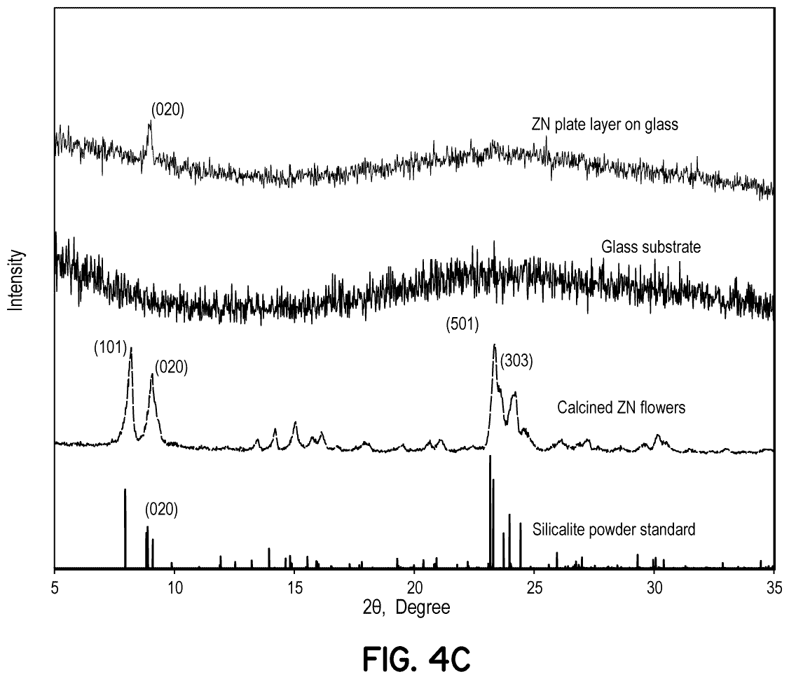

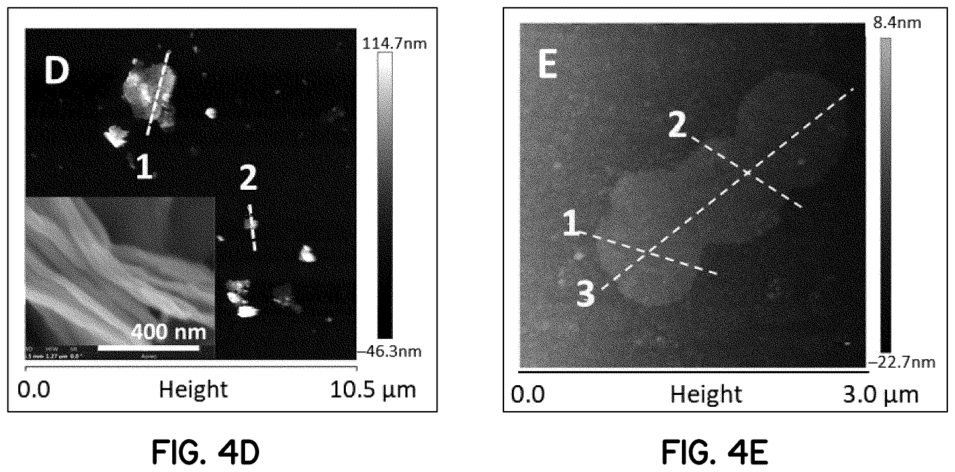

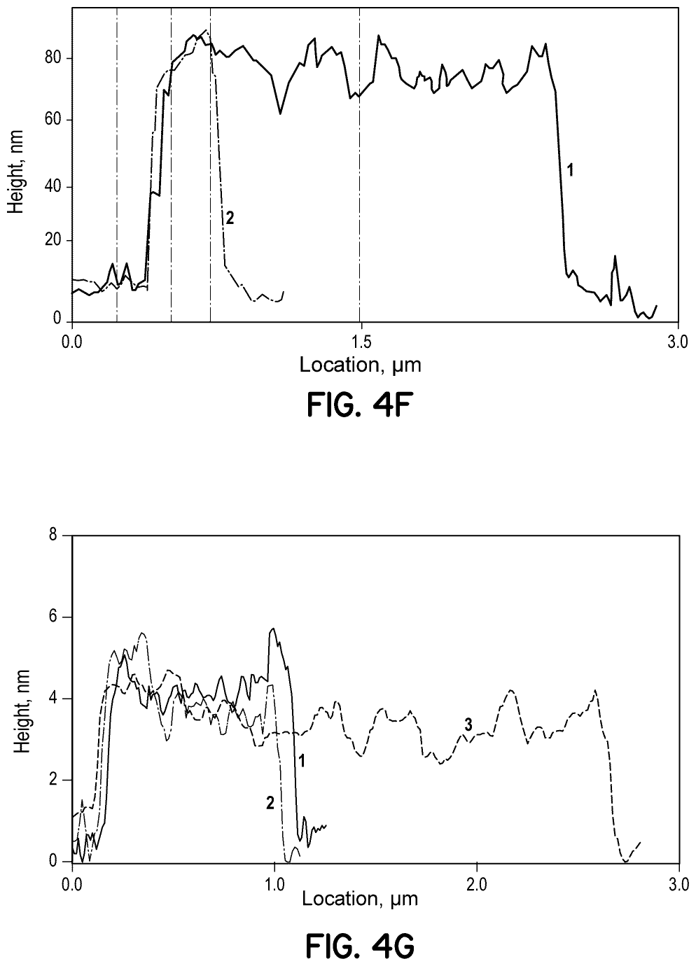

Higher-generation ZN assemblies (i.e., second-generation and onward) were grown from ZN flake seeds generated by fracturing and/or dissociating the flower petals from the previous generation ZN assembly. The ZN plate petals could be readily dissociated or fractured by sonicated ball-milling in water assisted by >−4 mm zirconia milling-beads to harvest flat ZN plates having large areas (FIG. 4D). Small ZN fragments obtained from sonicated ball milling were used as ZN flake seeds in further synthesis steps. The small ZN fragments from the first-generation ZN assemblies (FIG. 3B) were used as ZN flake seeds for growing the second-generation ZN assemblies (FIG. 3C) and small ZN fragments from the second-generation ZN assemblies (FIG. 3D) were used as seeds for the third-generation ZN assemblies (FIG. 3E).

After obtaining ZN flake seeds from the first-generation flower-like ZN assemblies, a single-step synthesis method was demonstrated for reproducing next generations of ZN flowers (FIG. 3A). The ZN flake seeds from previous generation ZN assemblies were then dispersed in a synthesis solution and subjected to hydrothermal treatment in an autoclave at 140° C. for 96 hours. The ZN flake seeds (FIGS. 1B and 1D) were mostly less than or equal to 0.5 μm in side-lengths and could be further ball-milled to increase the seed population. Specifically, the ZN flake seeds generated from fracturing the first-generation ZN assemblies were used to synthesize second-generation ZN assemblies and the flake seeds generated from fracturing the second-generation ZN assemblies were used to synthesize third-generation ZN assemblies. The synthesis solution included an SDA (dC5), a source of silica (TEOS), a solvent (water), and a base (potassium hydroxide) in a molar ratio of 3.75:80:20:12000.

The results of sonicated ball milling and hydrothermal treatments to form second and third-generation ZN assemblies were analyzed using SEM images, TEM images, an AFM height surveys, ED patterns, and XRD spectra.

### DISCUSSION

After subjecting the first-generation ZN assemblies (e.g., the flower-like structures discussed in Example 1) to sonicated ball milling, the resulting ZN plates were analyzed using SEM, TEM, and AFM height surveys. Upon inspection, the unfractionated flat ZN plates had typical areas larger than 1.5 μm×2.5 μm. The small ZN fragments used as ZN flake seeds were determined to have average side lengths less than or equal to 0.5 μm in side-lengths. The larger ZN plates could be further sonicated and/or ball-milled to increase the seed population if necessary.

The ZN plates separated from the flower-like assemblies were determined to be multilayered using TEM images and ED patterns of the plate edge (FIG. 4A). These multilayered ZN plates were determined to consist of single crystal sheets using TEM images (FIG. 4B). The ED patterns indicate that the individual single crystal ZN sheets had thickness in b-axis direction (FIGS. 4A and 4B). The ED patterns of the multilayered ZN plates reflect overlapping ZN layers having [010] orientation (i.e., in b-axis direction) (FIG. 4A). The ED pattern and lattice dimension confirm the [010] orientation of the single crystal sheet (FIG. 4B). The XRD spectra for the randomly packed ZN flowers and a glass-supported single layer ZN plates confirm the pure MFI zeolite phase and out-of-plane orientation in b-axis for the flat ZN plates (FIG. 4C). AFM height profiling results showed an average thickness of approximately 60 nm for the multilayered ZN plates (FIGS. 4D and 4F). This thickness was in reasonable agreement with SEM observation of the cross-section of a multilayered ZN plate (FIG. 3D).

The multilayered ZN plates were exfoliated to separate a single crystal sheet for ED analysis. ED patterns and lattice dimension of the exfoliated single crystal sheet confirms the [010] orientation. Exfoliation of the multilayered ZN plates did not happen appreciably during the sonicated treatments in the KOH solution, although a few single crystal sheets were observed in the suspension. However, limited exfoliation of the ZN-stacked plates occurred when the plates were treated by alternated freezing and thawing processes in organic solvents including iso-butanol, toluene, and xylenes. These exfoliated single nanosheets (FIG. 3E) had typical dimensions of 1.0 μm×2.5 μm with uniform thicknesses of around 4 nm (FIG. 3G) that gave aspect ratios of length/thickness (L/δ) of approximately 600 and width/thickness (W/δ) of approximately 250.

The second and third-generation ZN assemblies also formed flower-like structures such as the rose flower structure and the spiral leaf structure seen in the first-generation ZN assemblies. XRD spectra for the randomly packed ZN flowers and a glass-supported single layer ZN plates confirm the pure MFI zeolite phase and out-of-plane orientation in b-axis for the flat ZN plates.

### Example 3

### Methods

The flower-like ZN assemblies were calcined to remove SDA and other organic residue before analyzing the samples using a BET to determine adsorption-desorption properties of various gases. The calcination process to activate the ZN assemblies involved heating the ZN assemblies to 600° C. in air for 8 hours. The N₂ adsorption-desorption measurements were carried out for the ZN assemblies at 77 K before and after calcination.

A sample of conventional silicalite crystals was also examined by the BET for comparison. The conventional silicalite crystals were synthesized using an Al-free clear solution of TEOS as silica source and TPAOH as SDA. Both the ZN assembly and conventional crystal samples were thoroughly cleaned by the KOH solution before calcination activation. Before each adsorption measurements, the samples were dried at 393.15 K in a vacuum oven and further degassed at 523.15 K for 2.5 hours during measurements. These deep cleaning and evacuation processes were used to completely remove the amorphous silica and organic residues from the ZN surfaces and intra- and inter-ZN layer non-zeolitic pores.

The apparent transport diffusivity (D_{T}, m²/s) of p-xylene and o-xylene for the flower-like ZN assemblies and conventional crystals of pure silicalite were estimated under the transient state of dynamic uptake process. The nonequilibrium adsorption amount was taken at 30 seconds, which is far less than the equilibrating times of the tested xylene vapors. The D_{T} was estimated by the following uptake equation [3,4] with crystal sizes represented by the characteristic radius (=(3Vₚ)/Aₚ) for both multilayered ZN plates and the conventional crystals,

$${D}_{T} = {( \frac{{Q}_{30} - {Q}_{0}}{{Q}_{∞} - {Q}_{0}} )}^{2} {( \frac{{V}_{p}}{2 {A}_{p}} )}^{2} ( \frac{π}{t} ) \qquad ( 1 )$$

where Vₚ and Aₚ are the volume and total surface area of an individual zeolite particle (i.e., the ZN plate or conventional crystal); Q_{∞}, Q₃₀, and Q₀ are adsorption amounts recorded at equilibrium, t=30 seconds, and t=0 seconds, respectively. The use of xylene loadings at 30 second time mark ensured that the transient condition was far before equilibrium. Because of the intricate structures and relatively broad crystal size distributions, the D_{T} values were estimated using conservatively estimated upper and lower average size limits for each sample. For the ZN assemblies, the lower and upper limit average sizes of the constituting multilayered plates were (3 μm×3 μm×0.1 μm) and (5 μm×5 μm×0.06 μm), respectively; and for conventional crystals, these size limits were (2 μm×0.6 μm×0.2 μm) and (2.3 μm×0.8 μm×0.25 μm), respectively.

### DISCUSSION

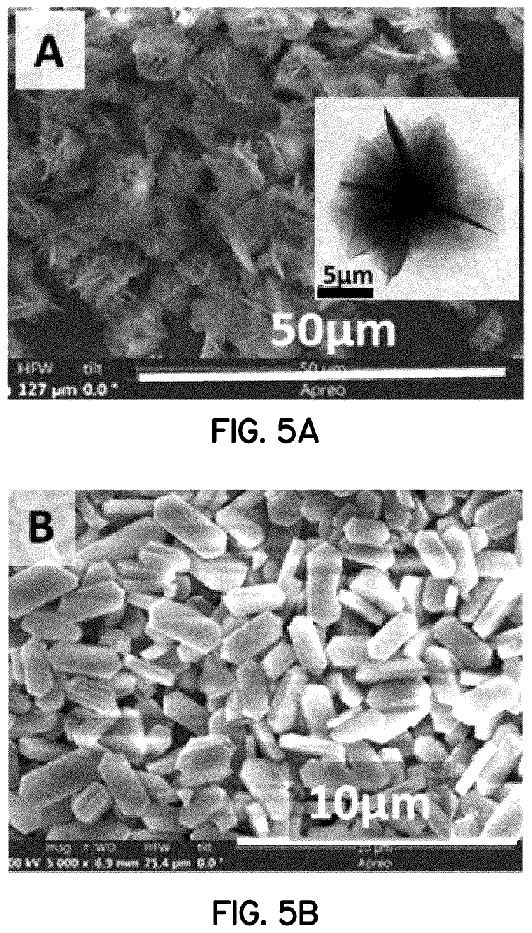

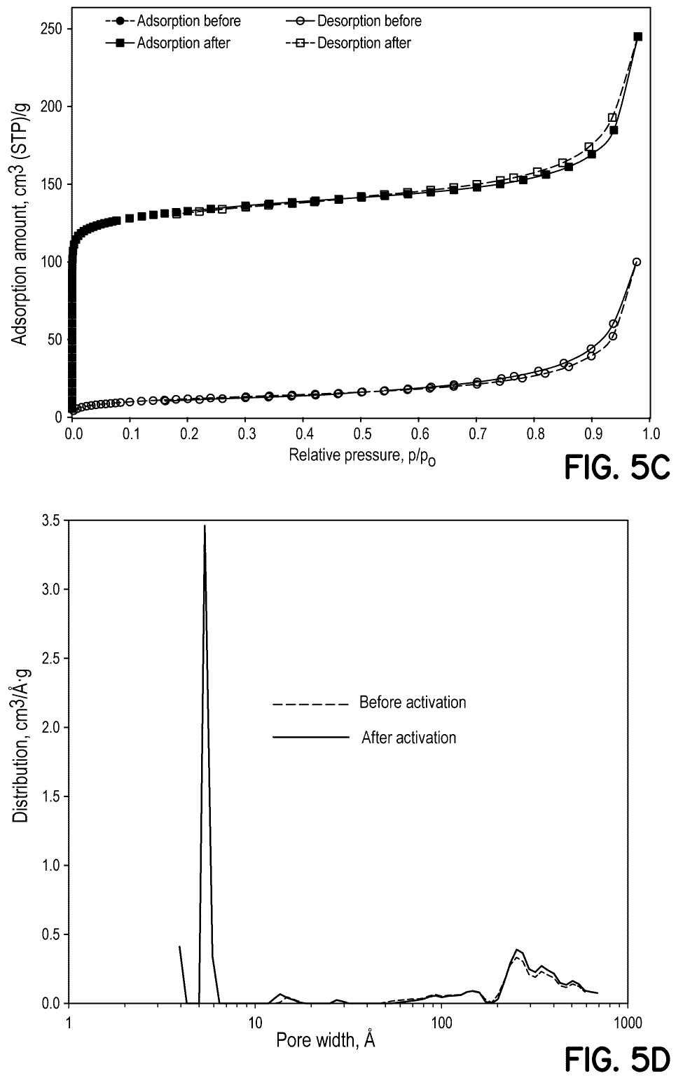

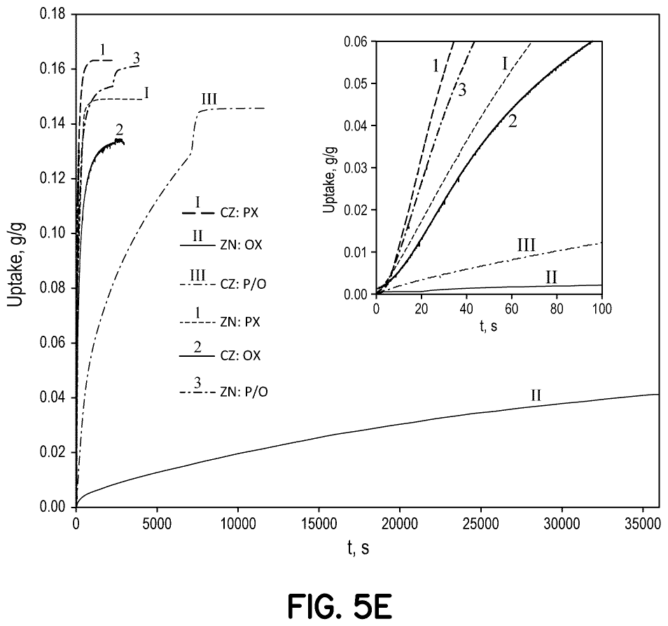

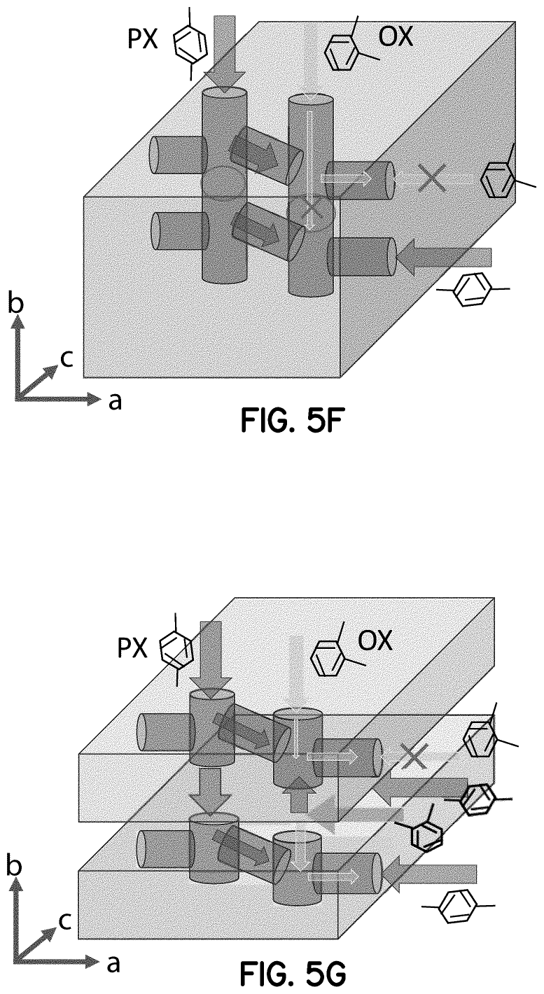

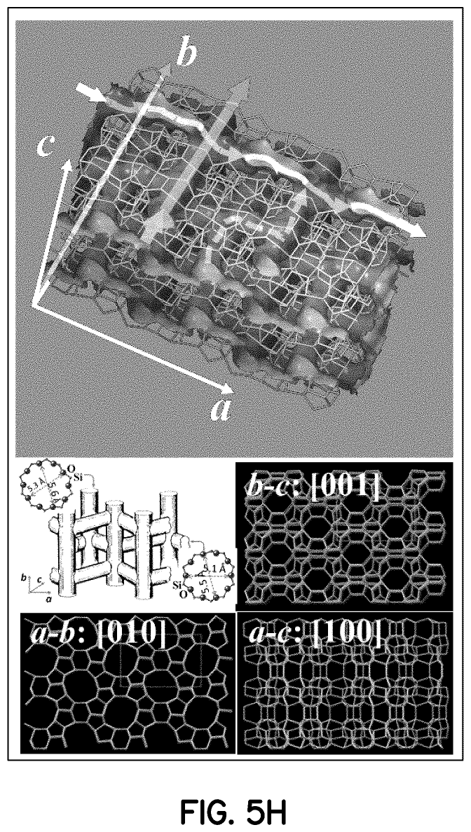

The flower-like second- and third-generation ZN assemblies were structurally stable during SDA removal by calcination at 600° C. and multiple cycles of adsorption-desorption tests. The flower-like open structures prevented the assembled ZN plates from collapsing that consequently preserved the inter-ZN spaces for facilitated molecular transport. SEM and TEM images of the flower-like ZN assemblies after calcination corroborate the structural integrity of the activated ZN assemblies after calcination (FIG. 5A). The ZN assembly samples of FIG. 5A were examined for its pore structure as well as molecular adsorption and transport properties in comparison with the conventional micron-sized silicalite crystals of FIG. 5B.

The N₂-adsorption-desorption isotherms at 77 K for the ZN assembly sample before and after thermal activation demonstrate BET surface areas for the ZN assemblies were 42 and 492 m²/g before and after SDA removal, respectively (FIG. 5C). The nonactivated ZN assemblies contained micropores with pore widths (dp) of 1.09-1.85 nm and two groups of mesopores with dp ranges of 4.7-17 nm and greater than or equal to 19 nm, respectively (FIG. 5D). The microporosity may be attributed to the intracrystalline defects and spaces between misaligned single crystal sheets, i.e., inter-sheet spaces evolved from defects in the nucleus surface (FIG. 8D). As verified using an AFM height survey, the single crystalline sheet was microscopically uneven with thickness varying between 3 and 4 nm that could form inter-sheet spaces of approximately 1-2 nm in width (FIG. 4G). The mesoporosity of the ZN assemblies were mainly inter-ZN plate spaces and some intracrystalline defects. The activated ZN assemblies exhibited a large volume of micropores with uniform dp of approximately 0.55 nm. This activated porosity corresponds to the MFI zeolitic channel sizes including the 0.53 nm×0.56 nm straight channels along b-axis and 0.51 nm×0.55 nm zigzag channels running in the a-c plane (FIG. 5H). The activated ZN assemblies also had non-zeolitic micropores and mesopores with size distributions virtually identical to those that existed in the nonactivated sample. This indicates that the inter-sheet micropores and inter-plate mesopores were well preserved after the calcination.

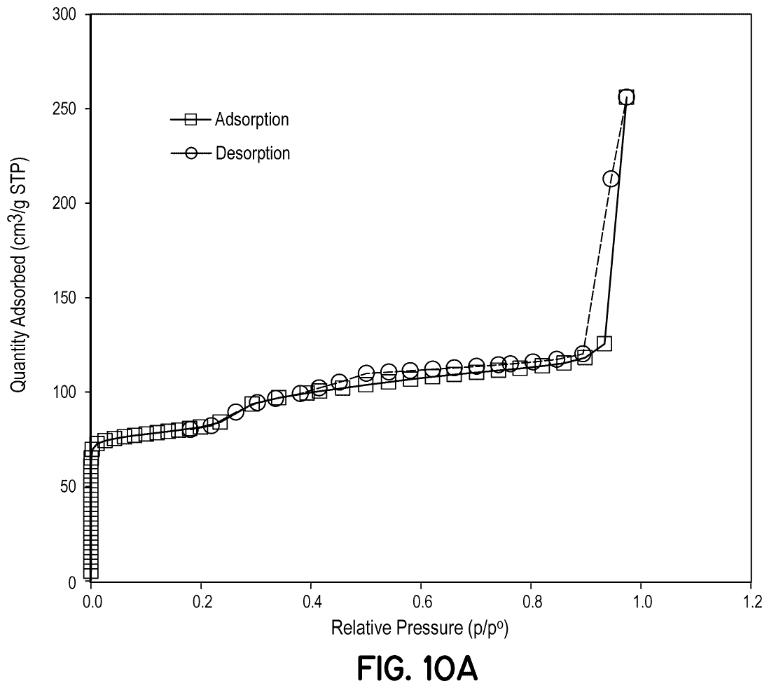

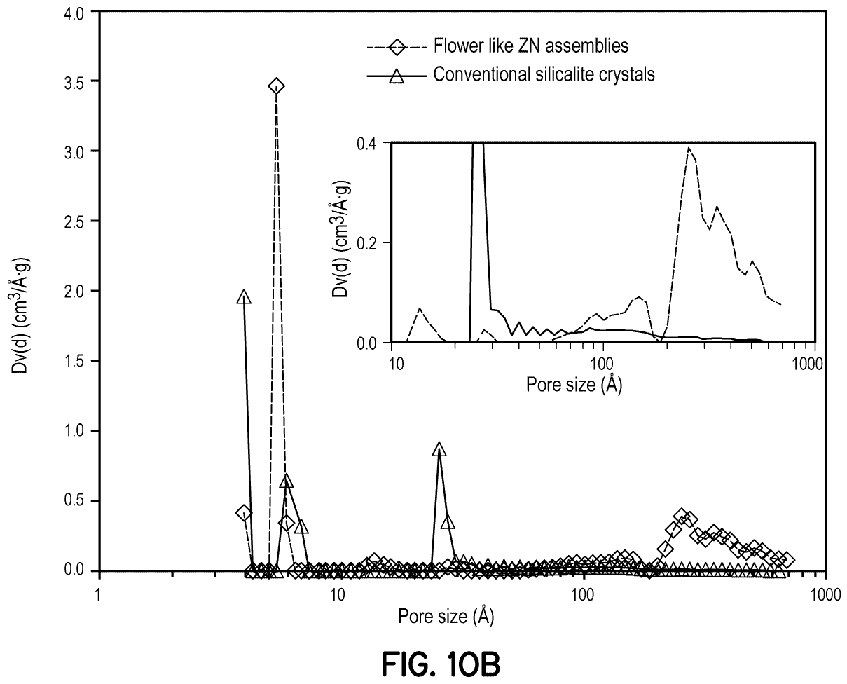

On the other hand, the microporosity with dp of 1.09-1.85 nm and mesoporosity with dp of greater than or equal to 4.7 nm were not observed in the conventional silicalite crystals (FIG. 10). This finding further evidenced the unique inter-sheet and inter-plate pore system in the ZN assemblies. However, the conventional silicalite crystals contained more mesopores with dp of approximately 2.7 nm after 1-week treatment by the KOH solution than the ZN assemblies (FIG. 10B). Such mesopore defects are common in large-size MFI zeolite crystals after leaching by strongly alkaline solutions. The conventional silicalite crystals had a BET surface area of 376 m²/g which is typical. The difference in BET area between the multilayered-ZN assemblies and conventional crystals was consistent with literature findings on the silicalite LZP assemblies, which was also attributed to the preserved inter-lamellar microporosity in the LZP. The BET surface area of the current ZN assemblies was slightly smaller than that of the LZP (520 m²/g) because the latter had smaller single sheet thickness (6 of approximately 2 nm) to form more inter-sheet boundaries.

To examine the accessibility of the zeolitic pores in the assemblies of multilayered ZN plates, dynamic adsorption was measured for p-xylene and o-xylene vapors at 300 K under a relative vapor pressure (p/pₒ) of approximately 0.5 (where saturation pressure pₒ=1.3 kPa) (FIG. 5E). The zigzag channels in a-c plane are inaccessible to the larger o-xylene but can be entered by the smaller p-xylene while the straight channels are accessible to both xylenes. Thus, xylenes are particularly suitable for probing the zeolitic pore accessibility in the ZN plates. Accessible paths for xylene to enter the zeolitic channels in conventional crystals and ZN plates are shown in FIGS. 5F and 5G respectively. FIG. 5H shows the simulated topological structure of the interconnected MFI channel system. The dynamic adsorption curves show that the ZN-assemblies had markedly greater adsorption amounts and faster uptake rates for the critically sized xylenes as compared to the conventional MFI crystals (FIG. 5E).

Table 1 below summarizes the equilibrium loading of xylene molecules in a unit cell (molc./u.c.) and the xylene apparent transport diffusivity (Dr) estimated by the uptake equation using the conventional characteristic radius (=(3Vₚ)/Aₚ) for particles of consideration. The MFI zeolites have theoretical xylene loading limit of 8 molc./u.c. around room temperature and p/pₒ=0.5. The loading of o-xylene in the conventional crystals were consistent with literature reports, which were slightly smaller than the theoretical value due to some inaccessible sites for the bulkier o-xylene molecule. The loadings of both xylenes in the ZN-assemblies were larger than those in the conventional crystals. The p-xylene loading in the ZN assembly exceeded the limit of 8 molc./u.c. because of the full accessibility of internal sites and additional inter-sheet sites for adsorption. The improved micropore accessibility also enhanced the o-xylene loading in the ZN plates as compared to the conventional crystals.

TABLE 1

| | Ads. Loading (molc./u.c.) | | D_{T} (10⁻¹⁶ m²/s) | |
|---|---|---|---|---|
| | ZN- | | ZN- | |
| Vapor | Assembly | Conventional | Assembly | Conventional |
| p-xylene | 8.8 | 8.1 | 238-662 | 415-722 |
| o-xylene | 7.3 | 6.0 | 64.4-179 | 0.95-1.65 |
| p-/o-xylene Mix | 8.7 | 7.9 | 179-498* | 16.6-28.9* |

*Pseudo D_{T} for xylene mixture vapor

Because of the complex structures and broad size distributions of the crystals, we estimated D_{T} between ranges of average size limits for the ZN plates in assemblies and the conventional crystals based on SEM observations (see FIG. 5). The p-xylene diffusivity in the conventional crystals was in good agreement with literature values measured by the uptake or breakthrough methods. The ZN assemblies exhibited D_{T} that was similar to that of the conventional crystals because both allowed p-xylene to enter and diffuse from the straight channels along b-axis as well the zigzag channels from the a-c direction (FIGS. 5F and 5G).

However, the D_{T} of o-xylene in the ZN-assembly was dramatically greater by about two orders of magnitude than that in the conventional crystals. Because of its larger kinetic size, o-xylene molecules could only enter the straight channels in b-axis and defuse extremely slowly through the large thickness of the conventional crystals (FIG. 5H). In the conventional crystals, the D_{T} of o-xylene was roughly 2-3 orders of magnitude smaller than p-xylene also because of the much higher energy barrier for the larger o-xylene molecules to enter and diffuse in the zeolitic channels. In the multilayered ZN plates, although the zigzag channels are inaccessible to o-xylene, the 1-2 nm width inter-sheet spaces allow fast transport in the layered structure and then enter the straight channels throughout the thickness (FIG. 5G). In addition, since the constituting single layers were only two cells in thickness (approximately 4 nm), the o-xylene molecules that exited from the inner side of the sheets could efficiently move around the inter-sheet spaces to enter the next layers without being blocked by the superimposed layers.

The unique interconnected mesopore and micropore system and the consequent efficient molecular transport mechanisms of the ZN plates were further corroborated by the dynamic adsorption behaviors of p-/o-xylene equimolar vapor mixture. In the conventional silicalite crystals, the pseudo-D_{T} derived from the mixture uptake curve was 10 times greater than that of the o-xylene but more than 20 times smaller than that of the p-xylene. Obviously, for the mixture, the intracrystalline diffusion of p-xylene is hindered by the slow-moving o-xylene in the long channels of the large crystals. In the ZN plates, the uptake rate and pseudo D_{T} for the p-/o-xylene mixture were comparable to those of the p-xylene. This confirms that the diffusion of p-xylene in the multilayered ZN plates was much less affected by the coexisting o-xylene because of the effective transport and distribution of xylene molecules through the inter-sheet spaces that is blocked by the o-xylene molecules.

### Example 4

### Methods

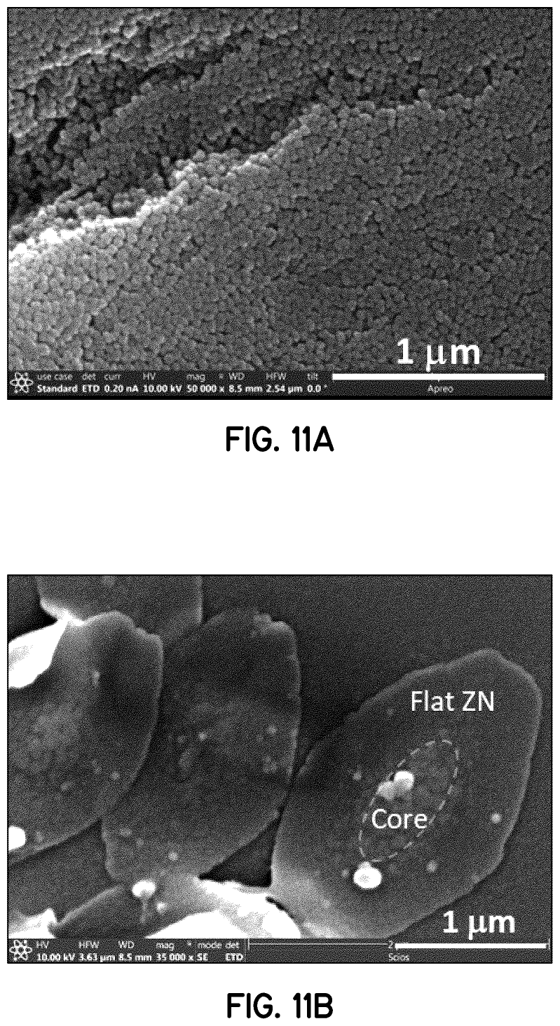

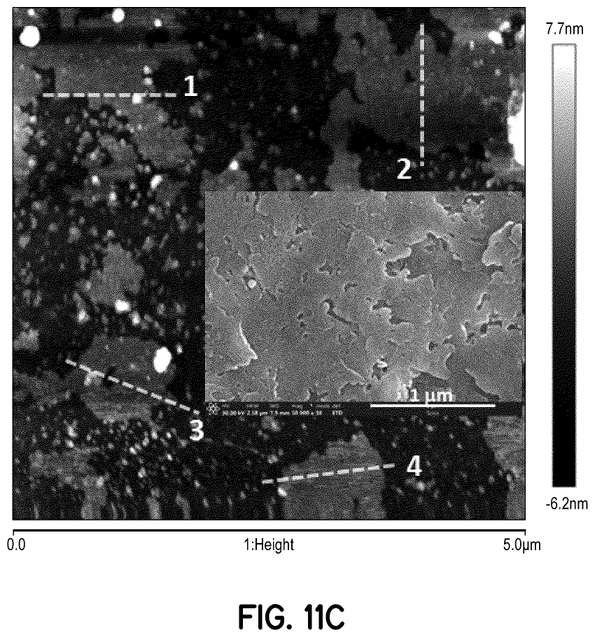

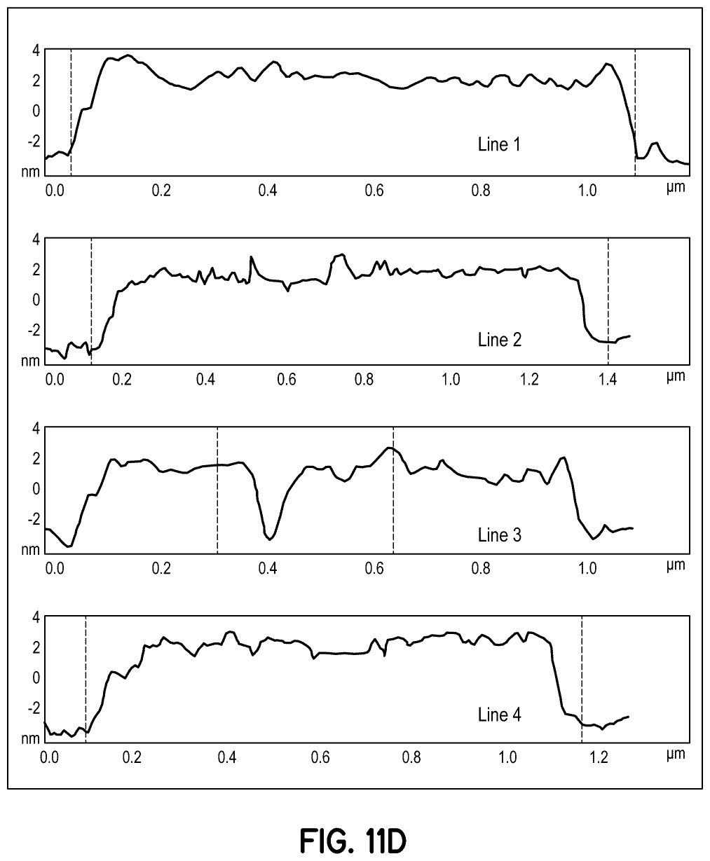

The crystals grown from the silicalite nanoparticle seeds (FIG. 11A) were in typical rhombus shapes (FIG. 11B) with each containing a seed-evolved high core encircled by a uniform single layer nanosheet. The flat ZN fragments were dissociated from the encircling sheets by sonication with zirconia milling balls and separated by centrifugation to remove the large debris from the center cores. These flat ZNs had unform thicknesses of approximately 4.5 nm (FIGS. 11C and 11D) along the b-axis of MFI cell coordinate, namely in the direction of straight channels with nearly circular pore opening of 0.54 nm×0.56 nm. These ZNs were further treated in the 0.1M KOH+1.0 M KCl solution to ensure complete removal of amorphous silica residuals from the surface and expose the active sites for secondary growth.

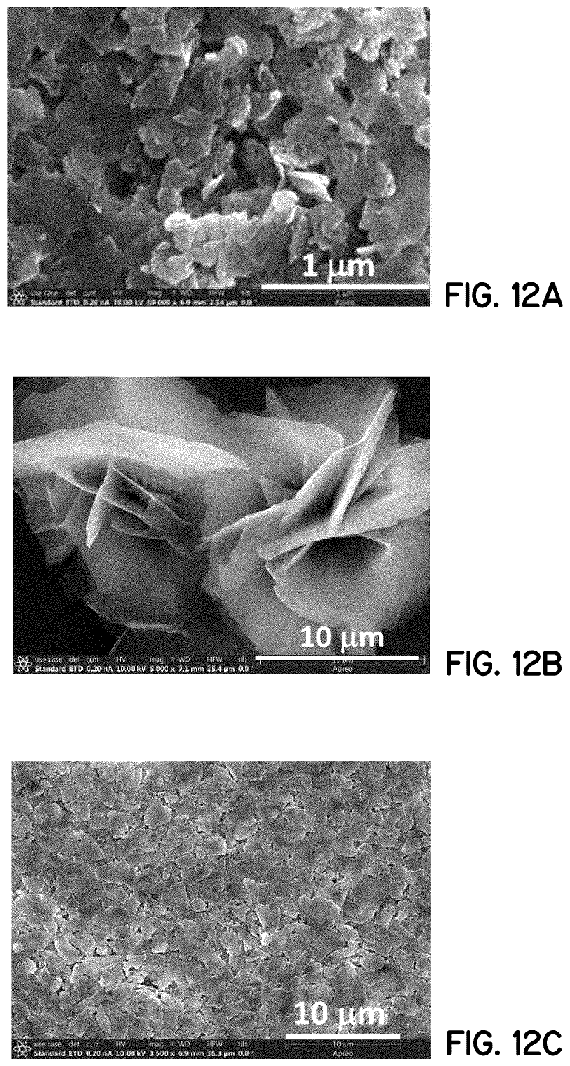

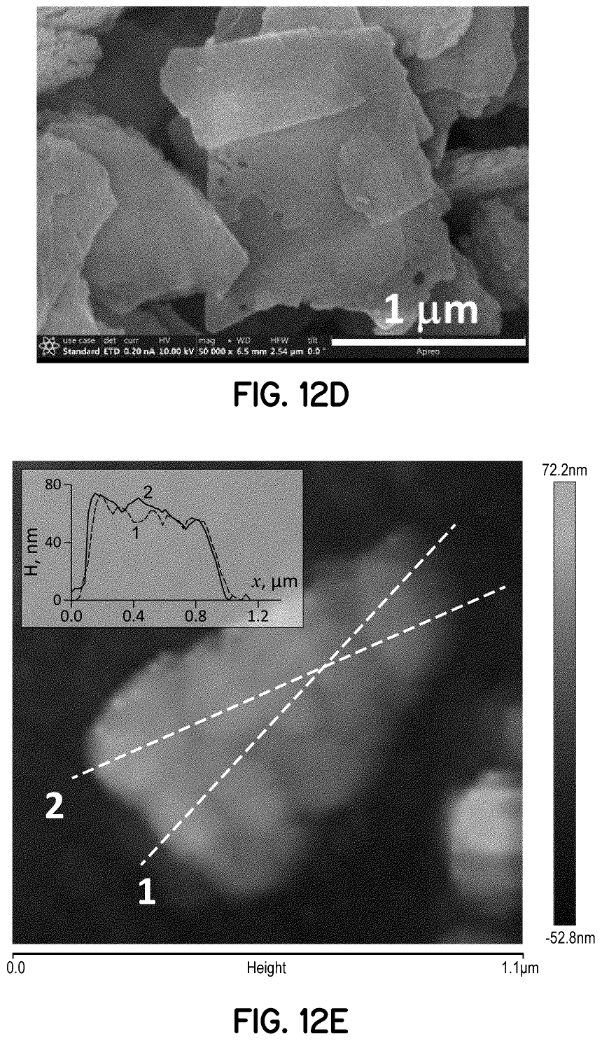

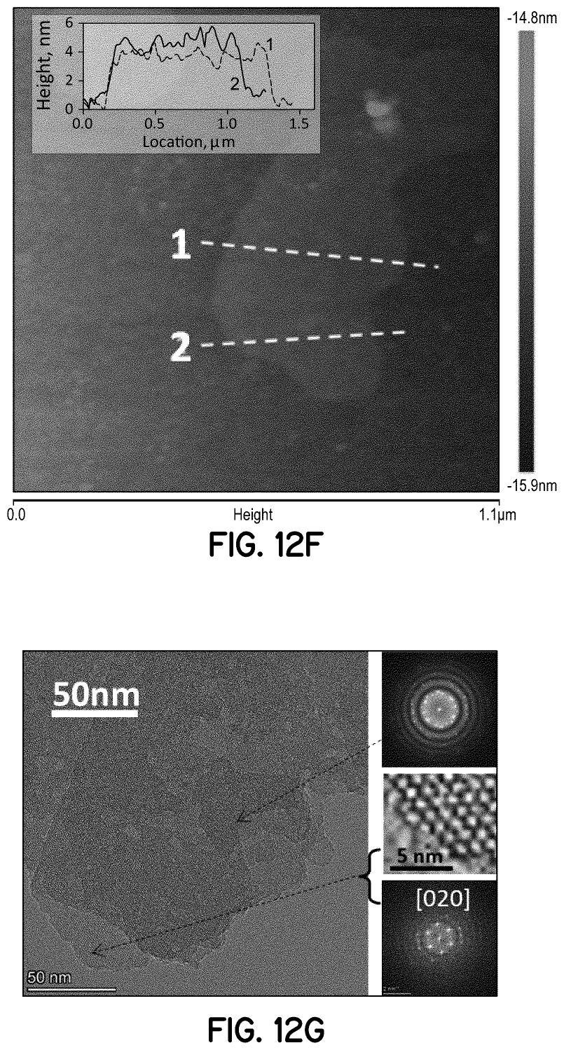

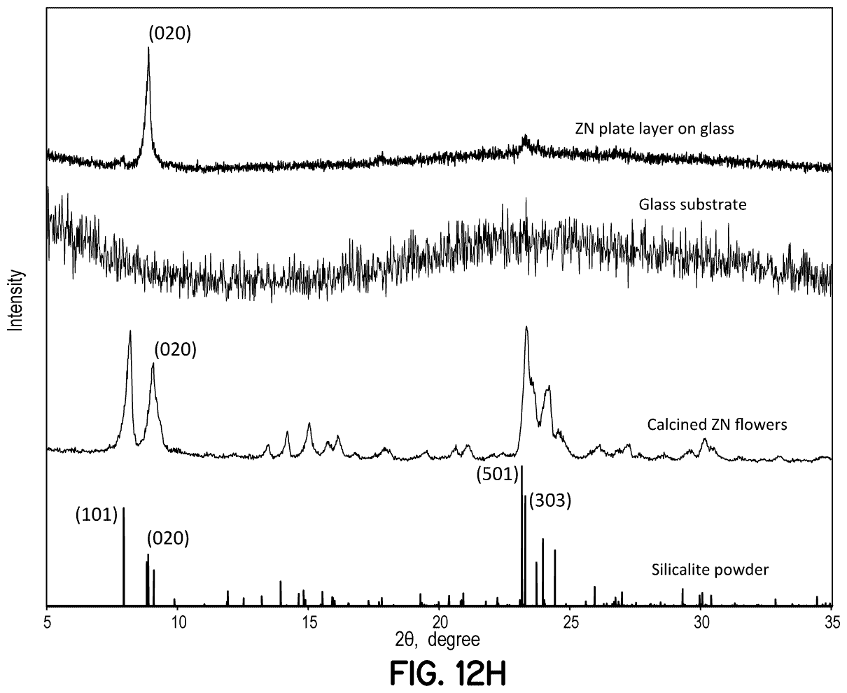

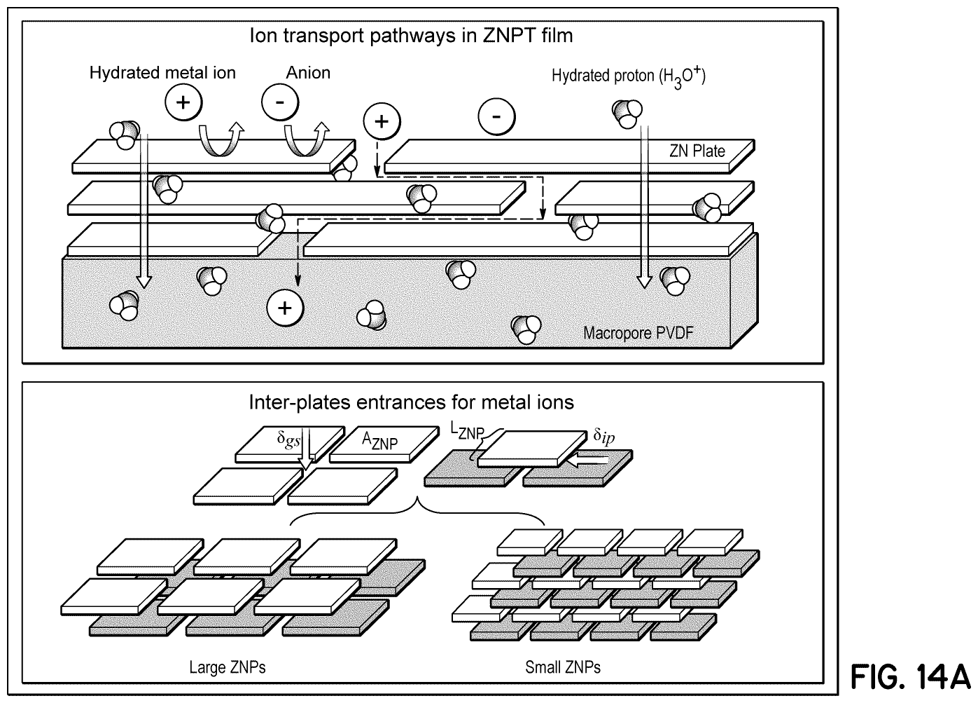

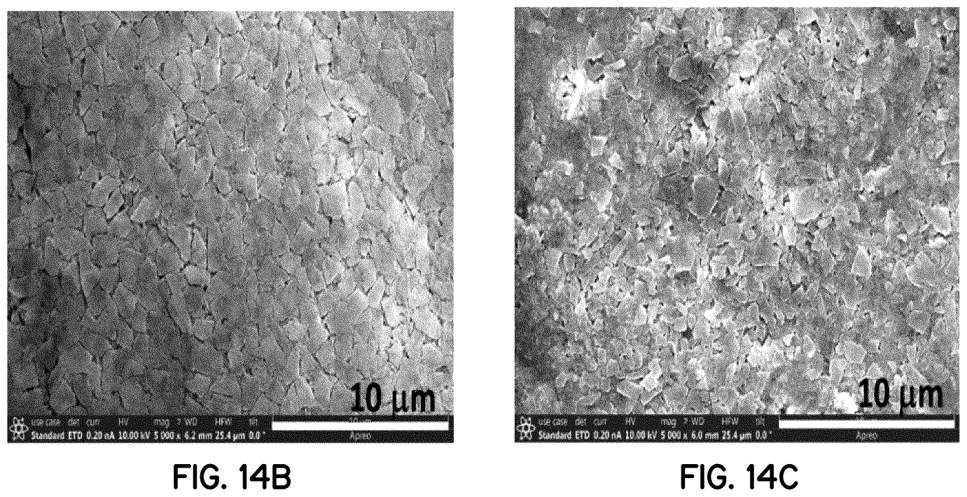

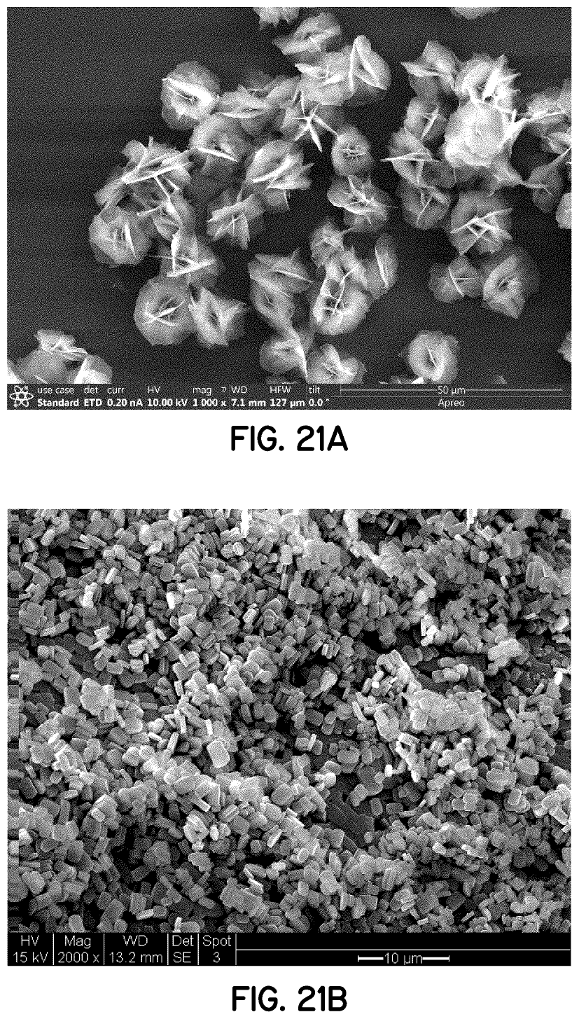

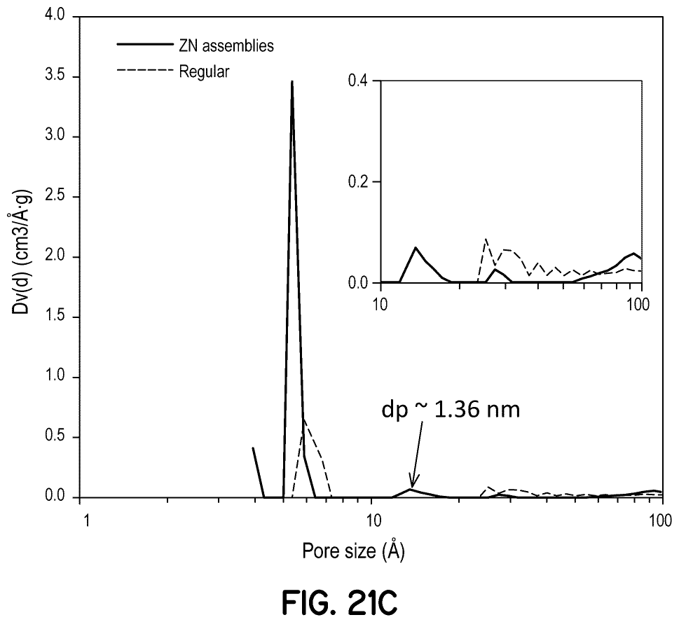

The single crystalline ZN seeds were further downsized to approximately 0.2×0.2 μm² (FIG. 12A) by intensive sonication in liquid EtOH with the zirconia milling balls. The ZN assemblies grown from the small ZN seeds had flower-like structures comprised of very large petals of ZN plates (FIG. 12B). After SDA removal by calcination, the ZN assemblies remained in flower-like open structures without collapsing (FIG. 21A). Flat ZN plates with lateral dimensions around 2.0 μm×2.0 μm (area approximately 4.0 μm², FIG. 12C) were obtained by sonication disintegration in EtOH and subsequent centrifugation fractionation processes. These ZN plates consisted of multiple layers of single crystalline ZNs as can be seen in the SEM image of ball-milled pieces (FIG. 12D) where the ZN underlayers were unveiled by secondary electron emission. The ZN plates had thicknesses of 60±10 nm according to the AFM examination (FIG. 12E) and the constituting single crystalline ZNs were approximately 4-nm-thick (FIG. 14F). The TEM and electron diffraction patterns showed that the stacked ZN layers and hence the entire ZN plate were oriented with its thickness in the b-axis direction (FIG. 12E). The XRD tests further confirmed pure MFI crystal phase for the ZN assemblies and out-of-plane (020)-orientation (i.e., along b-axis) for the ZN plate film tiled on glass (FIG. 12F).

The constituting single crystalline ZNs in the ZN plates are presumably bonded by condensation reaction (≡Si—OH+HO—Si≡→≡Si—O—Si≡+H₂O) between adjacent ZN surfaces, which could occur during the hydrothermal crystallization and calcination processes. The multilayered ZN plates had no evidence of delamination after sonication for two weeks in KOH (pH of approximately 13) and HCl (pH of approximately 1.0) solutions, respectively. Exfoliation of ZNs from the calcined plates was not observed during intensive sonication after three cycles of freezing and thawing in toluene and water, respectively. However, a few isolated single crystal ZNs were found in sonicated suspensions in the 0.1M KOH+1.0 M KCl solution after such freezing and thawing treatments of the nonactivated ZN plates (FIG. 12F). The results of BET tests for the ZN assemblies and conventional brick-shaped silicalite crystals (FIGS. 21B and 21C) found a small amount of micropores (approximately 0.005 cm³/g) in the ZN plates besides the zeolitic pore volume (0.165±0.010 cm³/g). These nonzeolitic micropores were micropore spaces between neighboring ZN surfaces with widths (d_{iz}) around approximately 1.4 nm, which were larger than the 0.56 nm zeolitic channels.

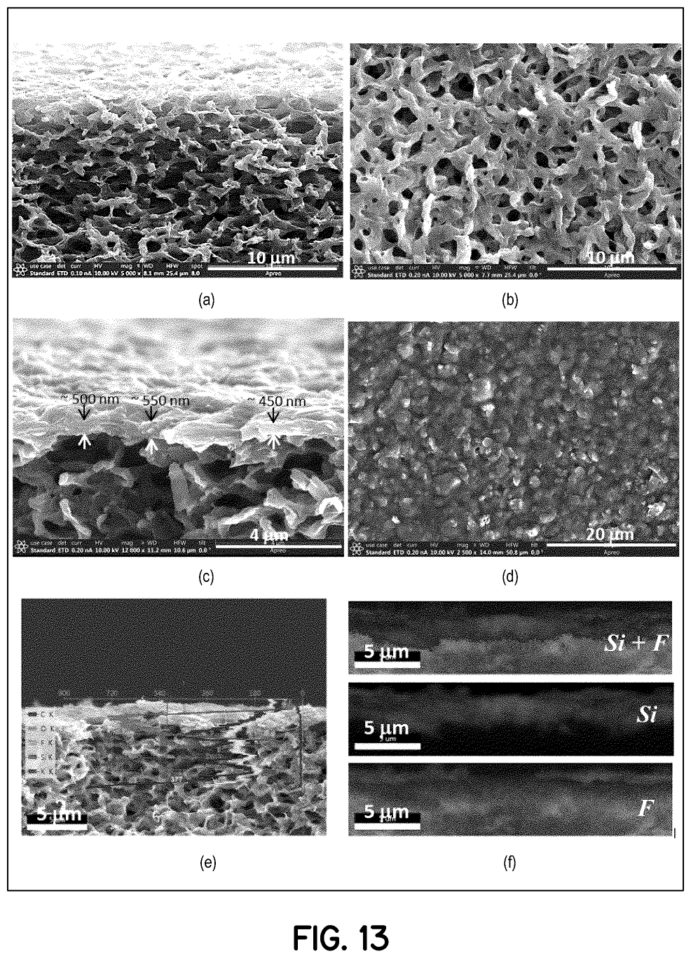

ZN plates were synthesized by sonicated ball milling of ZN assemblies produced by hydrothermal treatment of ZN flake seeds dispersed in a synthesis solution at 140° C. in an autoclave. The ZN assemblies were calcined at 600° C. for six hours to remove the SDA and activate the zeolite pores. For comparison purposes, ZN plates from assemblies activated via calcination were compared to nonactivated ZN plates using the same steps to produce each except for calcination. The ZN plates in the slurry (ZN mass@0.02 wt. %) were then dispersed in a polymer tiling solution including a polymer support (PVDF®0.06 wt. %), DMSO, and an organic solvent (ethanol), wherein the weight ratio of the ethanol to DMSO was 2:1. The PVDF substrate had a thickness of 125 μm, an effective pore size of approximately 0.45 μm, and a porosity (F_{PVDF}) of 83% according to the manufacturer specifications. The pore size in the PVDF film shown by the SEM images (FIGS. 13A and 13B) appeared to be dp of approximately 2 μm, which were larger than the manufacturer-stated average dp of 0.90 μm. The ε_{PVDF} was verified to be approximately 80% by weighing the film before and after soaking with ethanol (EtOH) and water.

Pinhole-free ZNPT thin membranes (FIGS. 13C and 13D) were obtained by single-time coating on a PVDF substrate using the vacuum-assisted filtration method. The hilly membrane surface (FIG. 13D) shows that the tiled ZN plates conformed to the rough surface of the macroporous PVDF substrate. The ZN plate-tiled PVDF substrate (i.e., the thus formed ZNPT-PVDF membrane) was then dried at 80° C. for 3 hours under vacuum and cured at 120° C. for 3 hours under vacuum.

The ZNPT-PVDF membranes after curing were experimentally studied for proton-selective ion transport and ion conduction in aqueous solutions, which are critical to applications as ion exchange membranes (IEMs). The tests used vanadium redox flow battery (RFB) electrolyte solutions as examples that is also of practical interest to electric energy storages. The ion diffusion measurements were conducted in a permeator with solutions circulated over a membrane area of 2.5 cm². The RFB single cell was used for electrochemical impedance spectroscopy (EIS), charge-discharge, and polarization curve measurements. The membrane working area was 1.2 cm×1.2 cm (=1.44 cm²) when mounted in the RFB cell. All the measurements were conducted at room temperature (approximately 25° C.) and ambient pressure.

For ion diffusion measurements, a solution of 4/7M VOSO₄+4/7M H₂SO₄ was circulated in the feed side and a 1M MgSO₄ solution was circulated in the permeate side for balancing ionic strength. The ion flux Jᵢ (mol/cm²·h) was obtained from the time-dependency of permeate ion concentration (C_{p,i}) in the linear region (i.e., the slope dC_{p,i}/dt) under constant feed concentration,

$${J}_{i} = ( \frac{{V}_{p}}{{A}_{m}} ) ( \frac{{dC}_{pi}}{dt} ) ; i = {H}^{+} , {V}^{4 +} ( V {0}^{2 +} ) \qquad ( 2 )$$

where the balancing solution volume in the permeate side was Vₚ=20 mL. The α_{H/V} is defined as the ratio of proton flux (J_{H+}) to vanadyl ion flux (Jᵥ₄₊).

The area specific resistance (ASR) of the membrane was measured in 2M H₂SO₄ solution by electrical impedance spectroscopy (EIS, Reference-600, Gamry Inc., USA). After the ion diffusion and ASR measurements, the ZNPT-PVDF membrane was tested as an ion separator for the vanadium RFB. The RFB charge-discharge and polarization curves were determined and compared with the commercially available Nafion117® membrane, which is a widely used benchmark IEM for RFBs. The polarization curves were obtained within a short time to minimize change of the state of charge (SOC=C_{V2+}(C_{V2+}+C_{V3+}) during measurement, so that the total cell ASR (ASR_{c}) can be estimated based on the linear section of the polarization curve.

### DISCUSSION

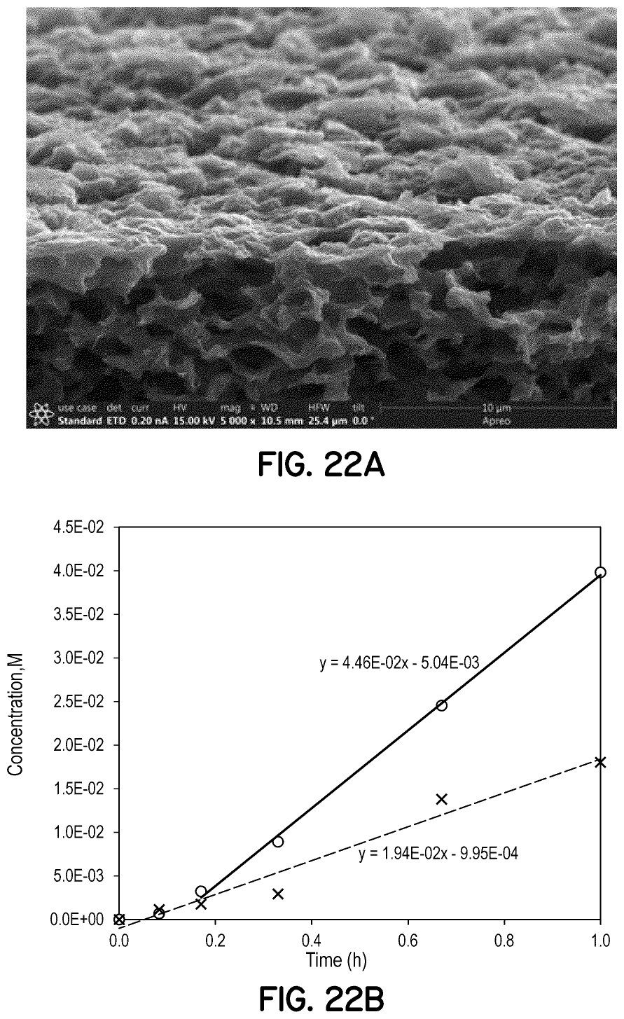

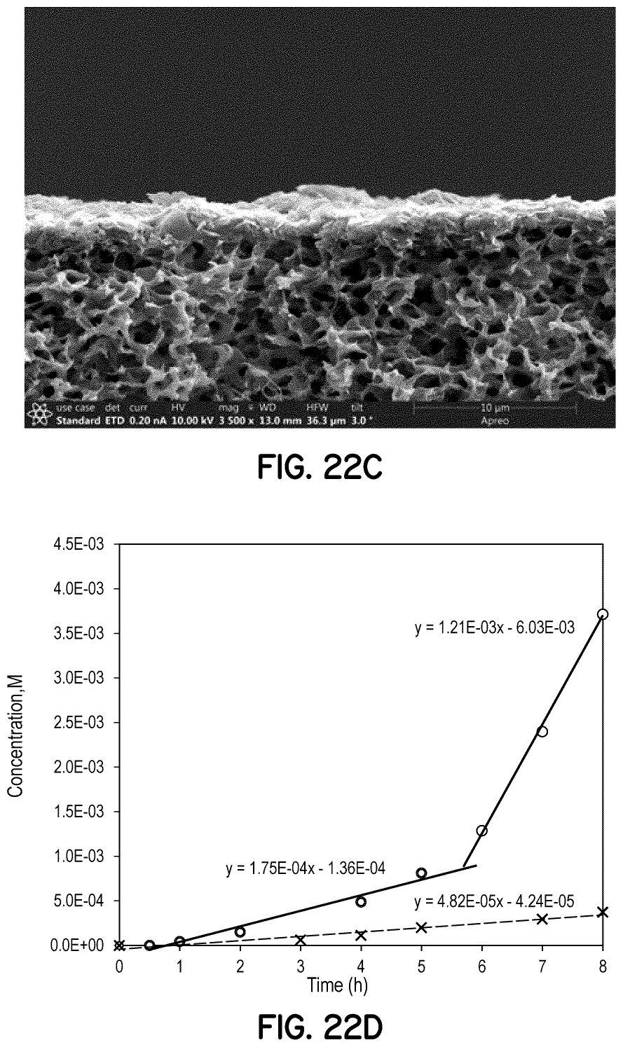

The very large ZN plates were able to bridge over the surface pore openings and pinholes were effectively eliminated by the self-repairing effect of the vacuum-assisted filtration coating mechanism (FIG. 19B). The results of elemental survey over the ZNPT-PVDF cross-section (FIGS. 13E and 13F) confirmed the existence of minimal PVDF binders in the ZNPT layer and absence of ZN plate penetration into the PVDF substrate porosity. However, uncovered spots or pinholes were often observed in thinner membranes formed from suspensions of much lower ZN plate contents (e.g., membrane from 0.01 wt. % ZN plates as shown in FIGS. 22A and 22B). On the contrary, defects of misaligned ZN plates tended to form in thicker membranes from suspensions of much higher ZN plate contents (e.g., membrane from 0.06 wt. % ZN plates shown in FIGS. 22C and 22D). The former had a drastically increased J_{H+} but with diminished α_{H/V} while the latter caused significant decreases of both J_{H+} and α_{H/V} (see Table 2 below).

Based on the silicalite single crystal density (ρ_{z}=1.76 g/cm³) and the 7.69·10⁻⁵ g/cm² ZN plate deposited on the surface, a thickness of 437 nm could be expected if the ZNPT layer were a single crystal. Because the volume of inter-ZN spaces (dᵢₛ of approximately 1.4 nm) was less than or equal to 3% of the total micropore volume of the ZN plates, the density of individual ZN plates is almost same as a single crystal. Thus, it could be estimated that the ZNPT film was stacked by about 7 layers of ZN plates for an average ZN plate thickness of 60 nm. Consequently, the inter-ZNPT space widths (δᵢₚ) in vertical direction were approximately 9 nm in the completely dry approximately 500-nm-thick ZNPT membrane. These nanometer-scale inter-ZN plate spaces were results of the microscopically uneven ZN plate surfaces (FIG. 12D) and the insertion of the PVDF polymer binders between layered ZN plates.

The ZNPT membrane layer had a bimodal pore system including intra-ZN plate zeolitic pores (dp of approximately 0.56 nm) and inter-ZN plate mesopores (δᵢₚ of approximately 9 nm). The inter-ZN micropores (dᵢₛ of approximately 1.4 nm) allow ion transfer through the multilayered ZN plates but not are not expected to affect the selectivity because the zeolitic pores determine the accessibility to ions by ion sieving effects. Thus, in the ZNPT layer, protons transport through both intra-ZN plate zeolitic pores and inter-ZN plate spaces, but the metal ions could only diffuse through the inter-ZN plate spaces (FIG. 14A). Apparently, it was the vertical inter-ZN plate spaces (Sip) rather than the surface gaps between horizontally laid ZN plates (δ_{gs}) that determined the inter-ZN plate transport rates because δᵢₚ was significantly less than δ_{gs} (FIG. 14A). The porosity of the inter-ZN plate entrances (εᵢₚ) thus depends on the area (A_{ZNP}) and perimeter (I_{ZNP}) of individual ZN plates. The εᵢₚ could be estimated to be approximately 2.0% based on δᵢₚ of approximately 9 nm and an average ZN plate dimension L_{ZNP} of 2.0 μm (FIG. 13C). Therefore, the Jᵢ and α_{H/V} of ZNPT membrane depend on the sizes and morphological uniformity of the ZN plates. Images of ZN plate layers tiled on smooth glasses show obviously smaller εᵢₚ in the film consisting of larger and more uniform ZN plates (FIG. 14B) than in the film of smaller and nonuniform ZN plates (FIG. 4c).

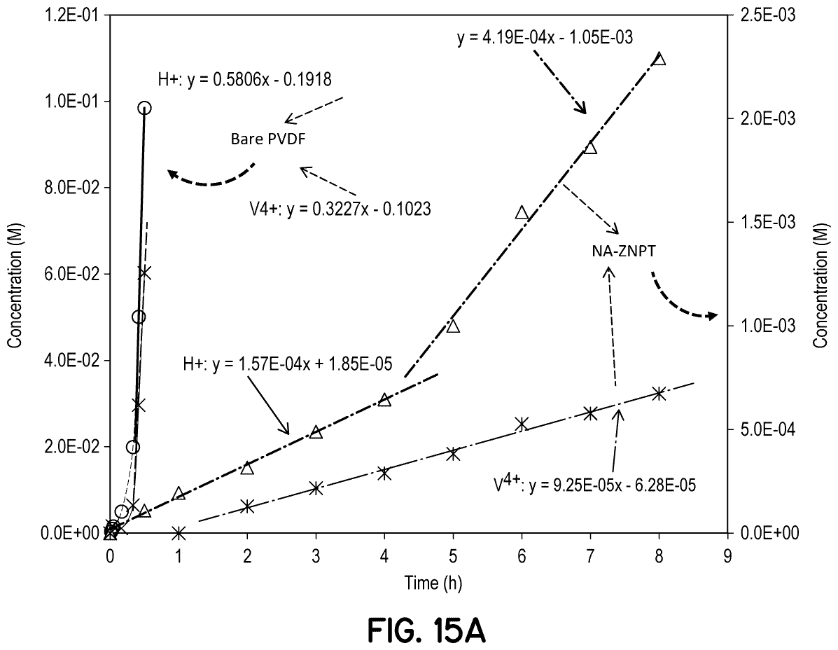

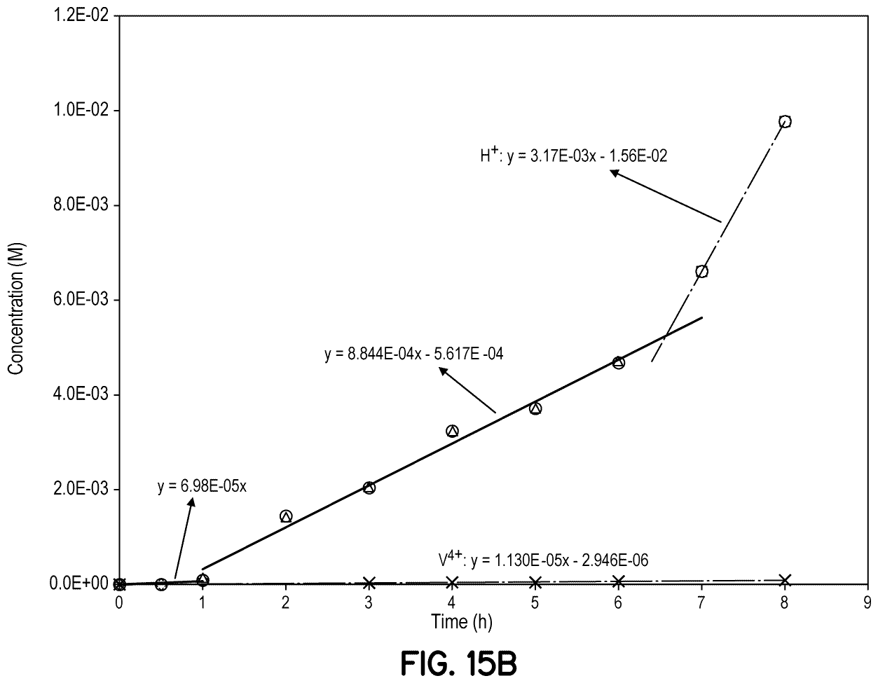

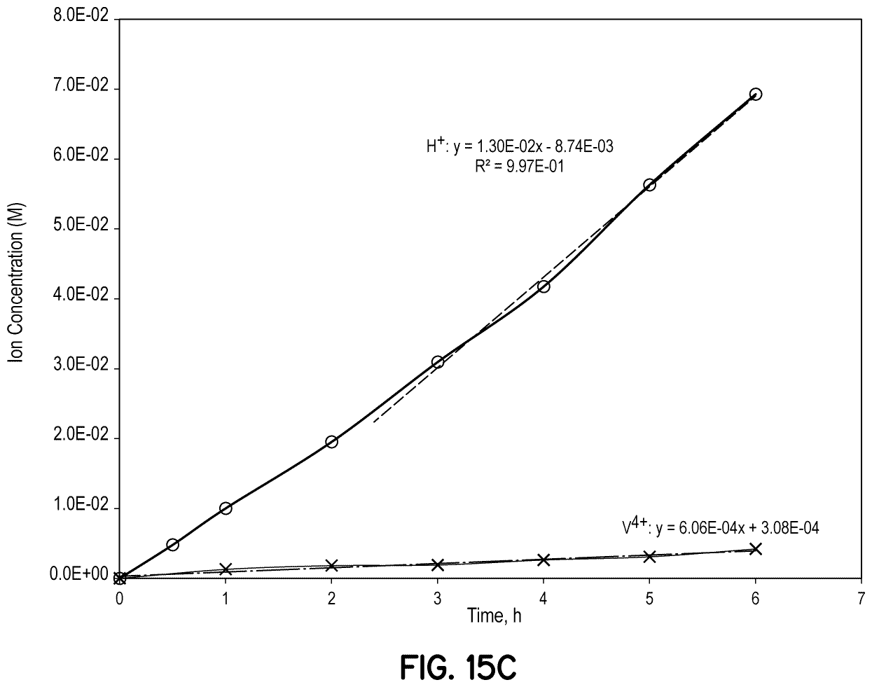

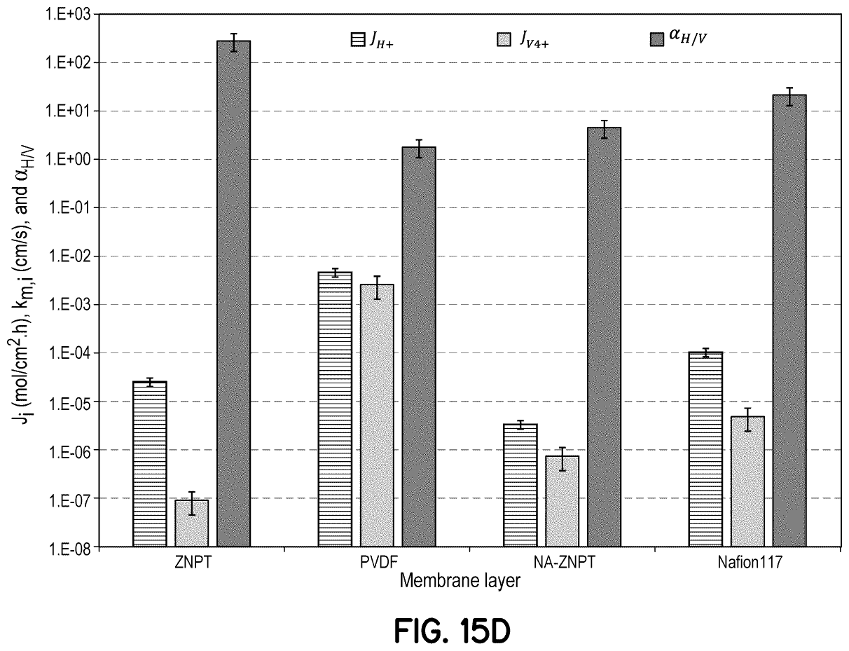

Results of ion diffusion tests demonstrated that, for the bare PVDF substrate, both C_{p,H+} and C_{p,V4+} increased rapidly after a relatively slow increase in the first approximately 0.3 hours (FIG. 15A). The brief transition in the beginning was caused by fast stabilization of concentration gradients across the macroporous film. The J_{H+} and J_{V4+} through the bare substrate were 8.10·10⁻³ mol/cm²·h and 4.50·10⁻³ mol/cm²·h, respectively, that gave an α_{H/V} of 1.8. Thus, the substrate was nonselective for the permeating ions as the selectivity would near unity (approximately 0.9) when normalized by driving forces, i.e., concentration differences between the two sides (Table 3).

TABLE 2

| ZN Plate | | | | |
|---|---|---|---|---|
| Content in | J_{H+}, | J_{V4+}, | | |
| suspension, wt. % | mol/cm² · h | mol/cm² · h | α_{H/V} | α′_{H/V}* |
| 0.01 | 6.19E−04 | 2.69E−04 | 2.3 | 1.2 |
| 0.02 | 4.40E−05 | 1.57E−07 | 280.5 | 140 |
| 0.06 | 1.68E−05 | 6.69E−07 | 25.1 | 13.0 |

TABLE 3

| Membrane | | Jᵢ, mol/h · cm² | | | |
|---|---|---|---|---|---|
| Layer | δₘ, μm | i = H⁺ | i = V⁴⁺ | α_{H/V} | α′_{H/V}* |
| Bare PVDF | 125 | 4.64E−03 | 2.58E−03 | 1.8 | 0.9 |
| Non Activated- | 0.50 | 3.35E−06 | 7.40E−07 | 4.5 | 2.3 |
| ZNPT | | | | | |
| ZNPT: Stage 3 | 0.50 | 2.54E−05 | 9.04E−08 | 280.5 | 140 |
| ZNPT: Stage 2 | 0.50 | 7.08E−06 | 9.04E−08 | 78.3 | 39 |
| ZNPT: Stage 1 | 0.50 | 5.58E−07 | 9.04E−08 | 6.2 | 3.1 |
| Nafion 117 ® | 183 | 1.04E−04 | 4.85E−06 | 21.5 | 10.8 |

$$* {a}_{H / V}^{′} = \frac{{J}_{H +} / ( {c}_{f , H} - {c}_{p , H +} )}{{J}_{V 4 +} / ( {c}_{f , V 4 +} - {c}_{p V 4 +} )}$$

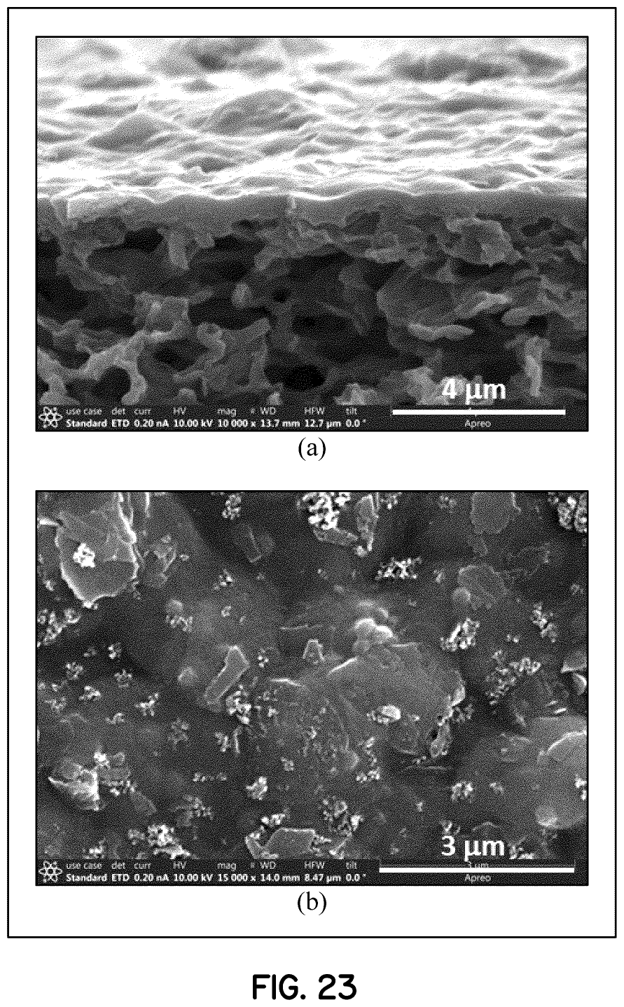

The membrane tiled by nonactivated ZN plates (NA-ZNPT-PVDF) had thickness and surface morphology that were about the same as those of the ZNPT-PVDF membranes (FIG. 23). It exhibited J_{H+} and J_{V4+} of 3.35·10⁻⁶ mol/cm²·h and 7.40·10⁻⁷ mol/cm²·h, respectively, which were only 0.041% and 0.016% of those on the bare substrate because of the impermeability of the nonactivated ZN plates. The J_{H+} experienced an approximately 4 hour transition period before stabilization (FIG. 15A). The slow stabilization of flux was likely caused by two factors: the first was the ZN plate surface protonation in the highly acidic solution that could develop ZN plate surface charges and slightly increase the Sip; and the second was the slow ion diffusion through the long-length zigzagged nanometer-scale inter-ZN plate spaces. The NA-ZNPT showed a small α_{H/V} of approximately 4.5 because of the nanometer-scale inter-ZN plate space sizes (δᵢₚ of approximately 9 nm).

The C_{p,H+} exhibited three distinct regions of time dependency for the ZNPT-PVDF membrane with increasing slopes (FIG. 15B). The membrane has low J_{H+} of 5.58-10⁻⁷ mol/cm²·h on average in the first hour that could be attributed to permeation through the inter-ZN plate spaces. The Intermediate region was likely resulted from inter-ZN plate space evolution by surface protonation/solvation, ion sorption inter-ZN micropores (dᵢₛ of approximately 1.4 nm) in ZN plates, and development permeation through mixed paths of intra-ZN plate and inter-ZN plate porosities. A J_{H+} of 7.08·10⁻⁶ mol/cm²·h was estimated for the middle stage. The J_{H+} reached 2.54·10⁻⁵ mol/cm²·h in about 6 hours. The vanadyl ions only could diffuse through the inter-ZN plate spaces, which had a very small porosity (εᵢₚ of approximately 2%). The C_{p,V4+} remained undetectable (detection limit of approximately 2.4·10⁻⁵ M) in the first 3 hours and showed a very small but nearly constant increasing rate afterwards. A J_{V4+} of 1.57·10⁻⁷ mol/cm²·h was estimated by assuming a constant flux for the entire time that led to an αH/V of approximately 280.

The surfaces of ZN plates were chemically different before and after calcination. The nonactivated ZN plates contained dC5 at the zeolitic pore mouths of external surface and at inter-ZN spaces within the ZN plates while the activated ZN plates were free of organics. These could different ZN surface ionization/solvation and inter-ZN plate space evolution behaviors in the electrolytes between the activated and nonactivated ZN plates. The organic-free silica surfaces are expected to be more readily protonated to form higher surface ionicity than the organic-containing surfaces. Consequently, the proton and vanadyl ion diffusion rates through the inter-ZN plate and inter-ZN (i.e., intra-ZN plate) spaces could vary in the Non-Activated (NA)-ZNPT and ZNPT layers. The ZNPT-PVDF exhibited dramatically higher J_{H+} that was caused by diffusion through the zeolitic pores. Meanwhile, it showed a substantially reduced J_{V4+} as compared to the NA-ZNPT. The smaller J_{V4+ of ZNPT membrane could be attributed to the greater surface protonation in the ZNPT, which created larger resistances to VO}²⁺ diffusion through the nanometer-scale inter-ZN plate spaces (δᵢₚ of approximately 9 nm).

Unlike the ZNPT-PVDF, the Nafion117® membrane had no appreciable ramp of proton permeation rate (FIG. 15C) because the fully hydrated sulfonated tetrafluoroethylene surface releases proton instantly upon contacting the pH-neutral solution. Because of its high concentration of solvated proton in the nanometer-scale water channels (dₚ of approximately 2.5 nm), the Nafion117® had a J_{H+} (1.04·10⁻⁴ mol/cm²·h), which was 4 times that of the ZNPT-PVDF. However, the relatively large-size water channels also allowed a J_{V4+ of} 4.85·10⁻⁶ mol/cm²·h that was 54 times that of the ZNPT-PVDF. The Nafion117® had an α_{H/V} of approximately 21.5, which was much lower than that of the ZNPT-PVDF (α_{H/V} of approximately 280). The ZNPT membrane was able to effectively restrict metal ion transport mainly because of its very small εᵢₚ (approximately 2.0%). The J_{H+} and J_{V4+} and α_{H/V} of different membranes obtained from the diffusion data in FIGS. 15A-15C are represented in FIG. 15D and are tabulated in Table 2 and 3 above.

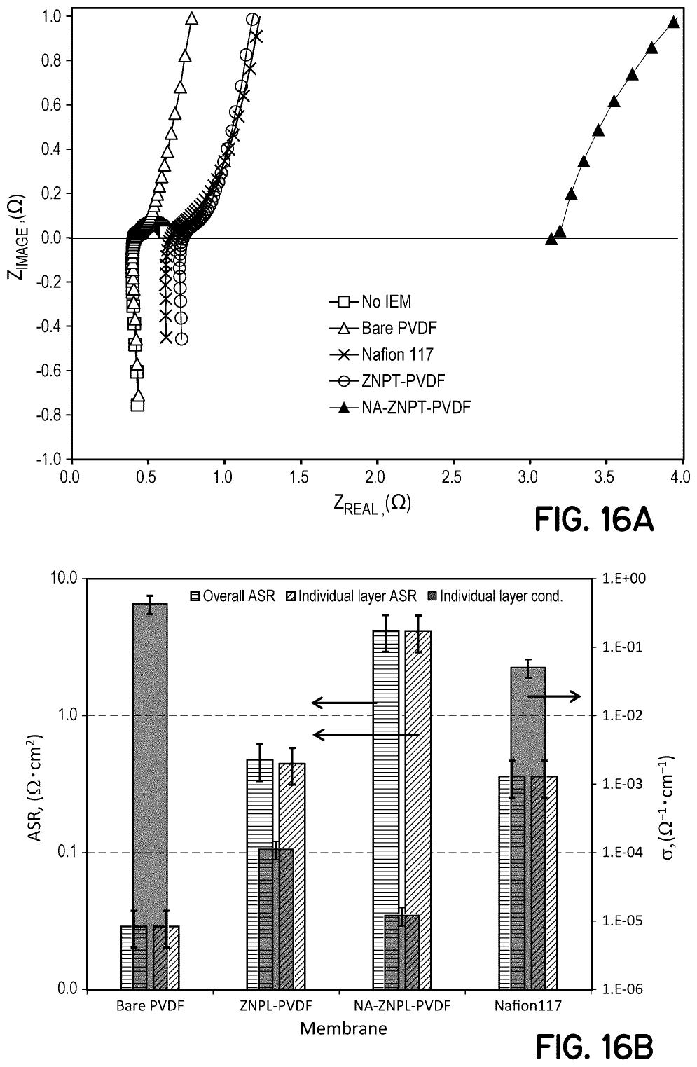

Results of the EIS measurements (FIG. 16A) demonstrated that the ASR of the individual membrane layers (ASRₘ; m=PVDF, ZNPT, NA-ZNPT, and Nafion117) were in the order of ASR_{PVDF} (0.029 Ω·cm²)<<ASR_{Nafion117} (0.36 Ω·cm²)<ASR_{ZNPT} (0.45 Ω·cm²) ASR_{NA-ZNPT} (4.15 Ω·cm²) (FIG. 16B). The ion conductivity of each layer (σₘ) estimated based on its thickness δₘ and ASRₘ, i.e., σₘ=δₘ/ASRₘ, were δ_{PVDF} of approximately 4.34·10⁻¹ Ω⁻¹·cm⁻¹, δ_{NA-ZNPT} of approximately 1.21·10⁻⁵ Ω·cm⁻¹, σ_{ZNPT} of approximately 1.12·10⁻⁴ Ω⁻¹·cm⁻¹, and σ_{Nafion117} of approximately 5.08·10⁻² Ω⁻¹·cm⁻¹. The difference of σₘ between the ZNPT and NA-ZNPT layers generally agrees with the difference of their J_{H+} (FIG. 15D), i.e., σ_{ZNPT}/σ_{NA-ZNPT}≈9.3 and J_{H+}(ZNPT)/J_{H+}(NA-ZNPT)≈7.6. This suggests that the ion transport rates through the inter-ZN plate spaces in the ZNPT membrane may be reasonably represented by the values of the NA-ZNPT layer. The σₘ is determined by the proton permeability of the membrane material, i.e., P_{b,H+}=C_{H+}D_{H+}, where C_{H+} and D_{H+} are H⁺ concentration and diffusivity in the membrane material, respectively. Thus, the highly ionic Nafion117 has much greater σₘ than the intrinsically nonionic ZNPT. Although σ_{Nafion} was approximately 450 times the σ_{ZNPT}, the ASR_{ZNPT} was only 1.25 times the ASR_{Nafion117} because the δ_{ZNPT} was far smaller than the δ_{Nafion117}.

The ZNPT-PVDF membrane was tested to function as an ion separator for the vanadium RFB equipped with carbon felt electrodes. The charge-discharge curves at constant current densities (i) and discharge polarization curves were measured using 10 mL catholyte solution containing 2M (VO₂)₂SO₄ (V⁵⁺)+2M (H₂SO₄) and 10 mL anolyte solution with 2M VSO₄ (V²⁺)+2M (H₂SO₄). The membrane ASR was reexamined by EIS measurements under the RFB operation conditions.

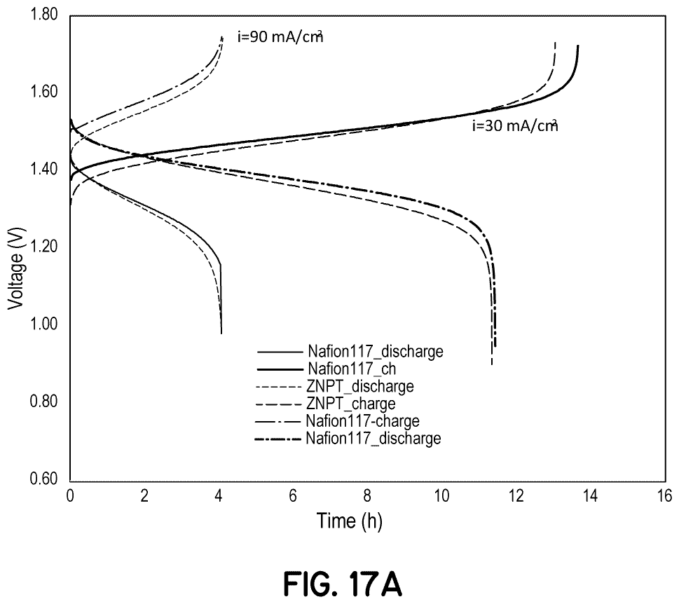

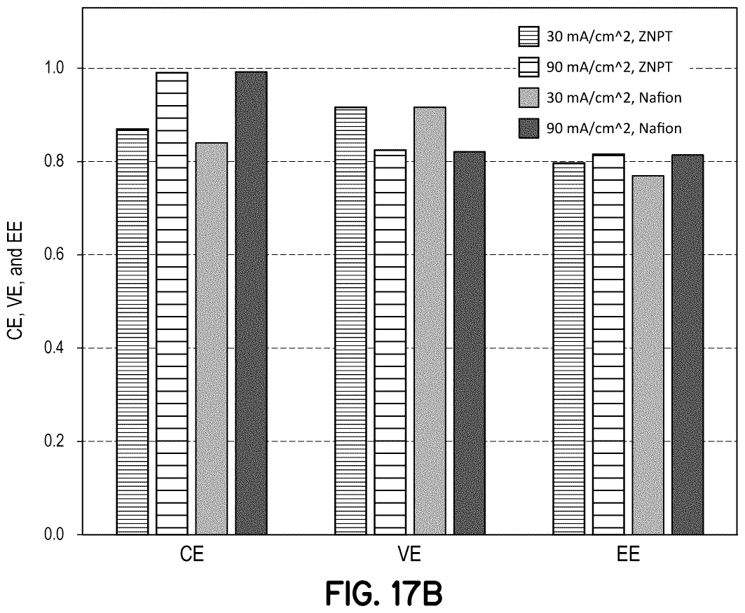

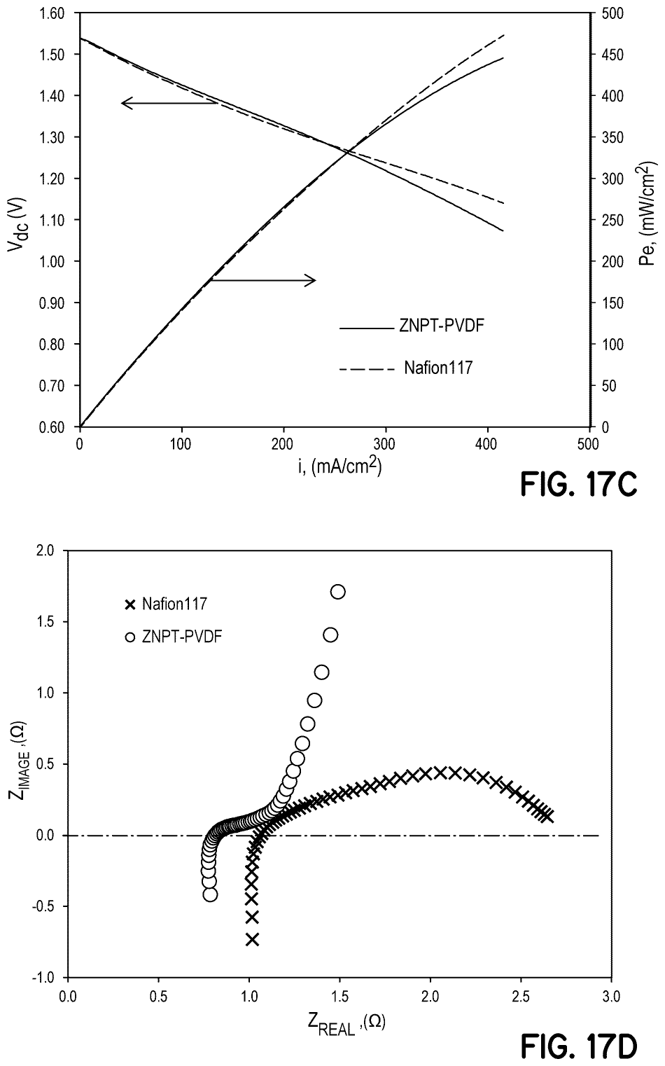

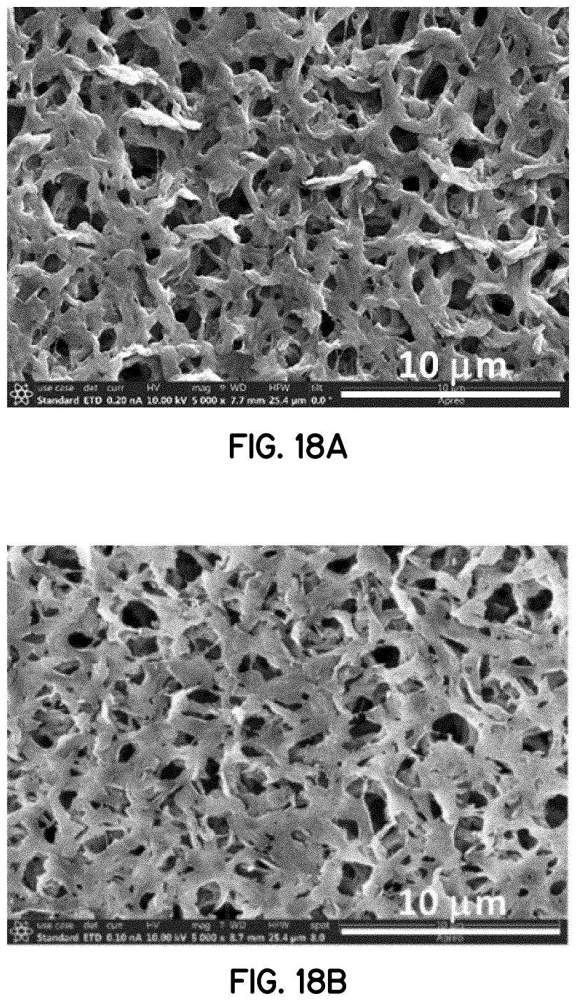

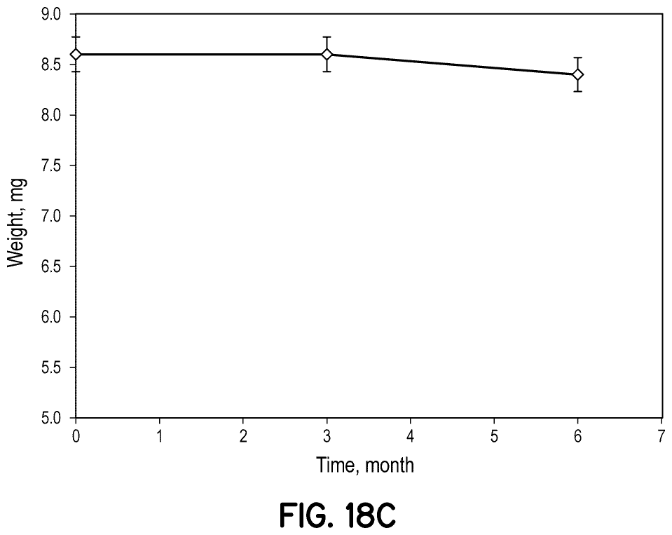

FIG. 17A presents the charge-discharge curves for the vanadium RFB equipped with ZNPT-PVDF and Nafion117 membrane, respectively. The RFB performed slightly better with the ZNPT-PVDF than with the Nafion117 membrane in terms of Coulombic efficiency (CE=[discharge time]/[charging time]), voltage efficiency (VE=[discharging voltage]/[charging voltage]), and energy efficiency (EE=CE×VE) (FIG. 17B). At a low i=30 mA/cm², the RFB with ZNPT-PVDF obtained slightly higher CE (approximately 87%) than that with the Nafion117 (approximately 84%). The better CE on the ZNPT-PVDF was caused by its high α_{H/V} that reduced metal ion crossover, especially over long operation times needed for low current densities. The CE was drastically enhanced for both membranes at a higher current density of 90 mA/cm² where the ZNPT-PVDF achieved CE of approximately 99% and EE of 82% and the Nafion117 obtained CE approximately 99% and EE approximately 81%.

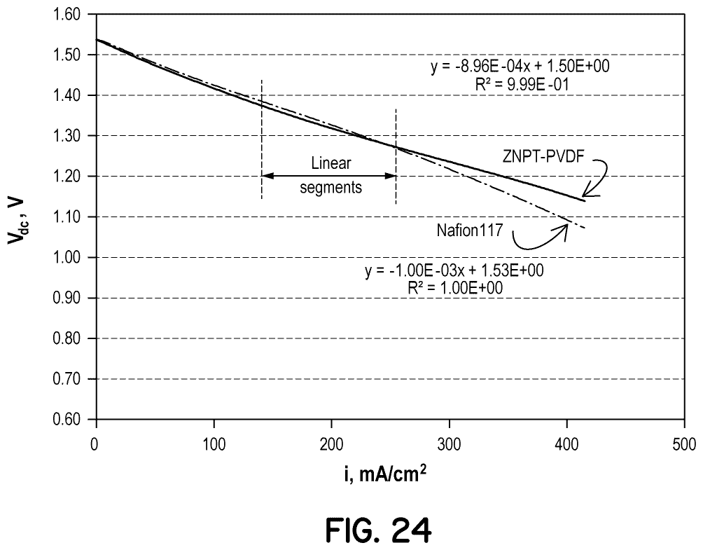

FIG. 17C presents polarization curves for the RFB when equipped with the ZNPT-PVDF and Nafion117 membrane, respectively, with the corresponding power density (Pₑ=i·V, mW/cm²). The linear sections of the curves (FIG. 24) were used to estimate the whole RFB cell and membrane ASR. The ASR of the ZNPT-PVDF was estimated from the polarization curve by excluding the resistances of other cell components (mainly including carbon electrodes and graphite current collectors). The thus-estimated ASR of the ZNPT-PVDF was approximately 0.71 Ω·cm², which was 50% higher than the value measured by EIS in the 2M H₂SO₄ solution (ASR of approximately 0.48 Ω·cm²). In contrast, the ASR of Nafion117 estimated derived from the polarization curve was approximately 0.86 Ω·cm², which was 140% higher than that measured by EIS in the 2M H₂SO₄solution (ASR of approximately 0.36 Ω·cm²). For confirmation, EIS measurements were also taken for the RFB after charging (FIG. 17D). The EIS measurements under RFB operation conditions also showed a smaller ASR for the ZNPT-PVDF (approximately 0.60 Ω·cm²) than for Nafion117 (approximately 0.95 Ω·cm²).

The substantial increase of ASR for Nafion117 in RFB operation conditions has been found to be primarily caused by the penetration of vanadium ions. The penetration and retention of vanadium ions contaminate the nanoscale water channels (dp of approximately 2.5 nm) that increases resistance to proton conduction in Nafion. Although vanadium ions can also enter the ZNPT layer through the very small amount of 9-nm-width inter-ZN plate spaces (εᵢₚ of approximately 2.0%), proton conduction in the membrane is much less affected because the zeolitic channels as the main pathways for proton transport are inaccessible to metal ions. Improved VE and Pₑ are hence expected from the ZNPT-PVDF over the Nafion117 because the former offers smaller ASR in RFB operation conditions to reduce internal Ohmic losses (=i·ASR), especially at relatively high current densities.

While the present invention has been illustrated by the description of one or more embodiments thereof, and while the embodiments have been described in considerable detail, they are not intended to restrict or in any way limit the scope of the appended claims to such detail. The various features shown and described herein may be used alone or in any combination. Additional advantages and modifications will readily appear to those skilled in the art. The invention in its broader aspects is therefore not limited to the specific details, representative apparatus and methods and illustrative examples shown and described. Accordingly, departures may be made from such details without departing from the scope or spirit of Applicants' general inventive concept.

What is claimed is:

1. A method of synthesizing flower-like zeolite nanosheet (ZN) assemblies from pure-silica MFI (silicalite) ZN flake seeds comprising:
(a) obtaining ZN flake seeds; and
(b) growing single-crystal nanosheets from the ZN flake seeds to form ZN assemblies in a synthesis solution comprising a source of silica and a structure directing agent (SDA).

2. The method of claim 1, wherein obtaining ZN flake seeds in step (a) is preceded by producing the ZN flake seeds, wherein producing the ZN flake seeds comprises:
(i) generating silicalite nanoparticles (NPs) in a silicalite synthesis solution comprising a source of silica and a structure directing agent (SDA) to produce NP seeds;
(ii) growing single crystalline silicalite ZNs from the NP seeds using a ZN precursor solution comprising an SDA to produce seed-evolved ZNs;
(iii) cleaning the seed-evolved ZNs; and
(iv) fracturing the cleaned seed-evolved ZNs to produce ZN flake seeds.

3. The method of claim 2, wherein the source of silica in the silicalite synthesis solution comprises tetraethyl orthosilicate (TEOS).

4. The method of claim 2, wherein the SDA of the silicalite synthesis solution comprises tetrapropyl ammonium hydroxide (TPAOH).

5. The method of claim 2, wherein the SDA of the ZN precursor solution comprises diquaternary bis-1,5(tripropyl ammonium) pentamethylene diiodide (dC5).

6. The method of claim 2, wherein the ZN precursor solution further comprises a source of silica.

7. The method of claim 6, wherein the source of silica of the ZN precursor solution comprises tetraethyl orthosilicalite (TEOS).

8. The method of claim 2, wherein the ZN precursor solution is hydrolyzed prior to step (ii).

9. The method of claim 2, wherein cleaning the seed-evolved ZNs comprises subjecting the seed-evolved ZNs to at least one base treatment step.

10. The method of claim 2, wherein cleaning the seed-evolved ZNs comprises subjecting the seed-evolved ZNs to at least one base-chloride treatment step.

11. The method of claim 2, wherein fracturing the seed-evolved ZNs comprises ball milling.

12. The method of claim 11, wherein fracturing the seed-evolved ZNs comprises sonicated ball milling in water

13. The method of claim 1, wherein the synthesis solution of step (b) comprises diquaternary bis-1,5(tripropyl ammonium) pentamethylene diiodide (dC5) as an SDA.

14. The method of claim 1, wherein the synthesis solution of step (b) comprises tetraethyl orthosilicalite (TEOS) as a source of silica.

14. The method of claim 14, wherein the synthesis solution of step (b) further comprises diquaternary bis-1,5(tripropyl ammonium) pentamethylene diiodide (dC5) as an SDA.

16. The method of claim 15, wherein the synthesis solution of step (b) further comprises a base.

17. The method of claim 15, wherein obtaining the ZN flake seeds in step (a) is preceded by producing the ZN flake seeds, wherein producing the ZN flake seeds comprises:
(i) obtaining a ZN assembly;
(ii) cleaning the ZN assembly; and
(iii) fracturing the ZN assembly to produce ZN flake seeds.

18. The method of claim 17, wherein obtaining a ZN assembly comprises obtaining a ZN assembly produced according to step (b).

19. The method of claim 17, wherein cleaning the ZN assembly comprises subjecting the ZN assembly to at least one base treatment step.

20. The method of claim 17, wherein cleaning the ZN assembly comprises subjecting the ZN assembly to at least one base-chloride treatment step.

21. The method of claim 17, wherein fracturing the ZN assembly comprises ball milling.

22. The method of claim 21, wherein fracturing the ZN assembly comprises sonicated ball milling in water.

23. The method of claim 1, wherein growing single-crystal nanosheets comprises growing multilayered ZN plates.

24. The method of claim 23, wherein the multilayered ZN plates comprise greater than or equal to 2 single crystal ZN sheets and less than or equal to 20 single crystal ZN sheets.

25. A method of producing a zeolite nanosheet plate-tiled (ZNPT) membrane comprising:
(a) obtaining ZN plates;
(b) dispersing the ZN plates in a polymer tiling solution comprising a solvent, an amount of dissolved polymer binders, and a binder solvent to form a ZN plate dispersion;
(c) tiling the ZN plate dispersion onto a polymer substrate to form a ZN plate layer;
(d) drying the ZN plate layer on the polymer substrate after step (c); and
(e) curing the ZN plate layer on the polymer substrate after step (d) to form a polymer-support ZNPT membrane.

26. The method of claim 25, wherein step (a) for obtaining ZN plates is preceded by producing the ZN plates, wherein producing the ZN plates comprises:
(i) obtaining a ZN assembly;
(ii) cleaning the ZN assembly; and
(iii) fracturing the ZN assembly to produce ZN plates.

27. The method of claim 26, wherein obtaining a ZN assembly comprises synthesizing a ZN assembly according to the method of claim 2.

28. The method of claim 26, wherein obtaining a ZN assembly comprises synthesizing a ZN assembly according to the method of claim 18.

29. The method of claim 26, wherein cleaning the ZN assembly comprises subjecting the ZN assembly to at least one base treatment step.

30. The method of claim 26, wherein cleaning the ZN assembly comprises subjecting the ZN assembly to at least one base-chloride treatment step.

31. The method of claim 26, wherein fracturing the ZN assembly comprises ball milling.

32. The method of claim 31, wherein fracturing the ZN assembly comprises sonicated ball milling in an organic solvent.

33. The method of claim 32, wherein the organic solvent comprises ethanol.

34. The method of claim 25, wherein the amount of dissolved polymer binders of step (b) comprises polyvinylidene fluoride (PVDF).

35. The method of claim 25, wherein the solvent of step (b) comprises ethanol.

36. The method of claim 25, wherein the binder solvent of step (b) comprises dimethyl sulfoxide (DMSO).

37. The method of claim 36, wherein the solvent of step (b) comprises ethanol.

38. The method of claim 37, wherein the weight ratio of ethanol to DMSO is 2:1.

39. The method of claim 25, wherein the ZN plates comprise greater than or equal to 0.01 wt. % by weight of the polymer tiling solution of step (b).

40. The method of claim 25, wherein step (c) comprises:
(i) placing the polymer substrate between the ZN plate dispersion and a downstream compartment; and
(ii) applying a pressure driving force to the ZN plate dispersion to tile the ZN plates onto the polymer substrate using filtration coating.

41. The method of claim 40, wherein applying a pressure driving force comprises applying a downstream vacuum.

42. The method of claim 40, wherein applying a pressure driving force comprises applying an upper stream pressurization.

43. The method of claim 26, wherein step (d) comprises subjecting the ZN plates on the polymer substrate to a temperature greater than or equal to 80° C. for a period of time greater than or equal to 3 hours.

44. The method of claim 43, further comprising pulling a vacuum at a pressure less than or equal to 1.5 kPa during step (d).

45. The method of claim 26, wherein step (e) comprises subjecting the ZN plates on the polymer substrate to a temperature greater than or equal to 120° C. for a period of time greater than or equal to 3 hours.

46. The method of claim 45, further comprising pulling a vacuum at a pressure less than or equal to 24 kPa during step (e).

47. The method of claim 26, further comprising:
(iv) activating the ZN assembly prior to fracturing the ZN assembly.

48. The method of claim 47, wherein activating the ZN assembly comprises calcination in air at a temperature greater than or equal to 400° C.
